(19) United States
(12) Patent Application Publication
(10) Pub. No.: US 2025/0338741 A1
(43) Pub. Date: Oct. 30, 2025

(54) DISPLAY PANEL AND MANUFACTURING METHOD FOR THE SAME

(71) Applicant: Samsung Display Co., Ltd., Yongin-si (KR)

(72) Inventor: HYUNEOK SHIN, Yongin-si (KR)

(21) Appl. No.: 19/056,555

(22) Filed: Feb. 18, 2025

(30) Foreign Application Priority Data
Apr. 30, 2024 (KR) 10-2024-0057778

(51) Int. Cl. H10K 59/131; H10K 59/12; H10K 59/123; H10K 59/124; H10K 102/00

(52) U.S. Cl. CPC H10K 59/1315; H10K 59/1201; H10K 59/123; H10K 59/124; H10K 2102/351

(57) ABSTRACT

A display panel that includes a circuit layer and a light emitting element on the circuit layer is provided. The circuit layer includes a semiconductor pattern, a first insulating layer including a first contact hole configured to expose a portion of the semiconductor pattern, a plurality of first connection electrodes on the first insulating layer and electrically connected to the semiconductor pattern through the first contact hole, and a second insulating layer configured to cover the plurality of first connection electrodes and on the first insulating layer. Each first connection electrode includes a first and second conductive layer. The second insulating layer includes a first sub-insulating layer between the first conductive layers adjacent to each other, and a second sub-insulating layer disposed on the first sub-insulating layer.

### CROSS-REFERENCE TO RELATED APPLICATION

This application claims priority to and the benefit of Korean Patent Application No. 10-2024-0057778, filed on Apr. 30, 2024, in the Korean Intellectual Property Office, the entire content of which is hereby incorporated by reference.

### BACKGROUND

The present disclosure pertains to a display panel and its manufacturing method, particularly on enhancing or improving the reliability of the display panel.

A display device includes a plurality of pixels and a driving circuit (e.g., a scan driving circuit and a data driving circuit) that manages or controls the plurality of pixels. Each of the plurality of pixels includes a display element and a pixel driving circuit that controls the display element. The pixel driving circuit may include a plurality of transistors that are interconnected in an organize manner (e.g., organically connected to each other). A connection electrode is electrically connected or linked to a semiconductor pattern of the transistor to transmit or convey one or more electrical signals to the transistor.

### SUMMARY

One or more aspects of embodiments of the present disclosure are directed toward a display panel including a connection electrode having high reliability (a display panel with a highly reliable connection electrode) and a method for manufacturing the same.

Additional aspects will be set forth in part in the description which follows and, in part, will be apparent from the description, or may be learned by practice of the presented embodiments of the disclosure.

According to an embodiment of the present disclosure a display panel includes: a circuit layer; and a light emitting element arranged on the circuit layer, wherein the circuit layer includes: a semiconductor pattern; a first insulating layer in which a first contact hole, through which a portion of the semiconductor pattern is exposed, is defined (e.g., the first insulating layer has or includes a first contact hole configured to expose a portion of the semiconductor pattern); a plurality of first connection electrodes arranged on the first insulating layer and electrically connected to the semiconductor pattern through the first contact hole; and a second insulating layer configured to cover the plurality of first connection electrodes and arranged on the first insulating layer, wherein each of the plurality of first connection electrodes includes a first conductive layer including (e.g., made of) aluminum and a second conductive layer arranged on the first conductive layer and including (e.g., also made of) aluminum, wherein the second insulating layer includes: a first sub-insulating layer arranged between the first conductive layers adjacent to each other (e.g., between a pair of adjacent first conductive layers); and a second sub-insulating layer arranged on the first sub-insulating layer configured to cover the second conductive layer, wherein the first sub-insulating layer includes a first inorganic material including silicon and a first organic material.

In one or more embodiments, the first organic material may include at least one of siloxane, polyimide, or an acrylic polymer, and the first inorganic material may include at least one of silicon dioxide (SiO₂), silicon nitride (Si₃N₄), or silicon oxynitride (SiON).

In one or more embodiments, the second sub-insulating layer may include a second organic material different from the first organic material.

In one or more embodiments, the first sub-insulating layer may be in contact with (e.g., on) a side surface of (e.g., each of) the first conductive layer(s) and may include a bottom surface that is aligned with a bottom surface of (e.g., each of the plurality of) the first conductive layer(s).

In one or more embodiments, a top surface of the first sub-insulating layer may be arranged below a top surface of (e.g., each of) the first conductive layer(s).

In one or more embodiments, at least a portion of a bottom surface of each of the second conductive layers may be in contact with (e.g., on) the first sub-insulating layer.

In one or more embodiments, at least a portion of a top surface of the first conductive layer may be in contact with (e.g., on) the second conductive layer, and a planar area of the top surface of the first conductive layer may be less than a planar area of a bottom surface of the second conductive layer.

In one or more embodiments, in a cross-section, a side surface of the first conductive layer and a side surface of the second conductive layer may be misaligned with each other.

In one or more embodiments, the second sub-insulating layer may be in contact with (e.g., on) a side surface and a top surface of each (e.g., of the) second conductive layer(s).

In one or more embodiments, the light emitting element may include a pixel electrode electrically connected to the plurality of first connection electrodes.

In one or more embodiments, the first conductive layer may include a first layer arranged on the first insulating layer and including titanium and a second layer arranged on the first layer and including aluminum, and the second conductive layer may include a third layer arranged on the second layer and including aluminum and a fourth layer arranged on the third layer and including titanium.

In one or more embodiments, the third layer may be arranged directly on the second layer, and a sum (e.g., total) of a thickness of the second layer and a thickness of the third layer may be at least about 10,000 angstrom Å (e.g., or more) and at most about 16,000 Å (e.g., or less).

In one or more embodiments, a second contact hole through which the plurality of first connection electrodes are exposed may be defined in the second 1 insulating layer, (e.g., the second insulating layer includes or has a second contact hole configured to expose the plurality of first connection electrodes), wherein the circuit layer may include: a second connection electrode arranged on the second insulating layer and electrically connected to at least a portion of the plurality of first connection electrodes through the second contact hole; and a third insulating layer configured to cover the second connection electrode and arranged on the second insulating layer.

In one or more embodiments, the second connection electrode may include a third conductive layer including aluminum and a fourth conductive layer arranged on the third conductive layer and including aluminum, wherein the third insulating layer may include: a third sub insulating layer configured to cover at least a portion of a side surface of the third conductive layer and including a first inorganic material including silicon and a first organic material; and a fourth sub insulating layer arranged on the third sub-insulating layer to cover the fourth conductive layer and including a second organic material different from the first organic material.

In one or more embodiments, the second contact hole may be defined in the second sub-insulating layer (e.g., the second sub-insulating layer may include the second contact hole).

In one or more embodiments of the present disclosure, a display panel includes: a circuit layer; and a light emitting element arranged on the circuit layer, wherein the circuit layer includes: a semiconductor pattern; a first insulating layer in which a first contact hole, through which a portion of the semiconductor pattern is exposed, is defined (e.g., a first insulating layer includes or has a first contact hole configured to expose a portion of the semiconductor pattern); a plurality of first connection electrodes arranged on the first insulating layer and electrically connected to the semiconductor pattern through the first contact hole; and a second insulating layer configured to cover the plurality of first connection electrodes and arranged on the first insulating layer, wherein each of the plurality of first connection electrodes 1 includes a first conductive layer including aluminum and a second conductive layer arranged on the first conductive layer and including aluminum, wherein the second insulating layer includes: a first sub-insulating layer arranged between the first conductive layers adjacent to each other (e.g., between a pair of adjacent first conductive layer); and a second sub-insulating layer arranged on the first sub-insulating layer, wherein at least a portion of a bottom surface of the second conductive layer is in contact with (e.g., on) the first sub-insulating layer.

In one or more embodiments of the present disclosure, a method for manufacturing a display panel includes: providing a semiconductor pattern and a first insulating layer arranged on the semiconductor pattern; and forming a plurality of first connection electrodes arranged on the first insulating layer and electrically connected to the semiconductor pattern; and forming a second insulating layer that covers the plurality of first connection electrodes, wherein the forming of the plurality of first connection electrodes and the forming of the second insulating layer includes: forming a plurality of first conductive layers including aluminum on the first insulating layer; providing a filling material between the plurality of first conductive layers to form a first sub-insulating layer that covers at least a portion of a side surface of each of the first conductive layers; forming a plurality of second conductive layers including aluminum on the plurality of first conductive layers; and forming a second sub-insulating layer that covers the plurality of second conductive layers, wherein the filling material includes a first inorganic material including silicon and a first organic material.

In one or more embodiments, the forming of the first sub-insulating layer may further include ashing a top surface of each of the first conductive layers after the providing of the filling material between the plurality of first conductive layers.

In one or more embodiments, a top surface of the first sub-insulating layer may be (e.g., formed to be defined) below a top surface of each of the plurality of first conductive layers.

In one or more embodiments, the forming of the plurality of first conductive layers may include: forming a preliminary first layer including titanium on the first insulating layer; forming a preliminary second layer including aluminum on the preliminary first layer; and patterning the preliminary first layer and the preliminary second layer, wherein the forming of the plurality of second conductive layers may include: forming a preliminary third layer including aluminum on the plurality of first conductive layers; forming a preliminary fourth layer including titanium on the preliminary third layer; and patterning the preliminary third layer and the preliminary fourth layer.

According to one or more embodiments, an electronic device may include a display device that includes the display panel of the present disclosure.

According to one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (loT) device, a smartwatch, a watch phone, or a head-mounted display (HMD).

### BRIEF DESCRIPTION OF THE DRAWINGS

The accompanying drawings are included to provide a further understanding of the preceding and other aspects, features, and advantages of certain embodiments of the present disclosure, and are incorporated in and constitute a part of this specification. The drawings illustrate embodiments of the present disclosure and, together with the description, serve to explain principles of the present disclosure. In the drawings:

FIG. 1A is a perspective view of a display device according to one or more embodiments of the present disclosure;

FIG. 1B is an exploded perspective view of the display device according to one or more embodiments of the present disclosure;

FIG. 2 is a cross-sectional view of a display panel according to one or more embodiments of the present disclosure;

FIG. 3 is a plan view of the display panel according to one or more embodiments of the present disclosure;

FIG. 4 is an equivalent circuit diagram of a pixel according to one or more embodiments of the present disclosure;

FIG. 5 is an enlarged cross-sectional view illustrating a portion of the display panel according to one or more embodiments of the present disclosure;

FIG. 6A is a cross-sectional view illustrating a portion of a configuration of the display panel according to one or more embodiments of the present disclosure;

FIG. 6B is a cross-sectional view illustrating a portion of the configuration of the display panel according to one or more embodiments of the present disclosure;

FIGS. 7A and 7B are flowcharts illustrating a method for manufacturing a display panel according to one or more embodiments of the present disclosure; and

FIGS. 8A-8H are cross-sectional views illustrating some processes of a method for manufacturing a display device according to one or more embodiments of the present disclosure.

### DETAILED DESCRIPTION

Hereinafter, example embodiments of the present disclosure will be described with reference to the accompanying drawings, and in which example embodiments of the present disclosure are shown. The present disclosure may, however, be embodied in different forms and should not be construed as limited to one or more embodiments set forth herein. Rather, these embodiments are provided so that this disclosure will be thorough and complete, and will fully convey the scope of the present disclosure to those skilled in the art.

In this specification, it will also be understood that if (e.g., when) one component (or region, layer, portion, and/or the like) is referred to as being ‘on’, ‘connected to’, or ‘coupled to’ another component, it can be directly connected/coupled on/to the one component, or an intervening third component may also be present.

Like reference numerals refer to like elements throughout, and duplicative descriptions thereof may not be provided. Also, in the drawings, the thickness, ratio, and dimensions of components may be exaggerated for clarity of illustration. In other words, because sizes and thicknesses of components in the drawings are arbitrarily illustrated for convenience of explanation, the following embodiments are not limited thereto.

The term “and/or” includes any and all combinations of one or more of the associated listed items. Expressions such as “at least one of,” “one of,” “selected from,” and “selected from among,” when preceding a list of elements, modify the entire list of elements and do not modify the individual elements of the list. For example, throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

It will be understood that although the terms such as ‘first’ and ‘second’ and/or the like are used herein to describe one or more suitable elements, these elements should not be limited by these terms. The terms are only used to distinguish one component from other components. For example, a first element referred to as a first element in one or more embodiments can be referred to as a second element in one or more embodiments without departing from the scope of the appended claims. The terms of a singular form such as “a,” “an,” and “the” may include plural forms unless referred to the contrary.

Spatially relative terms, such as “under”, “below”, “above', “upper”, and/or the like are used for explaining relation association of components illustrated in the drawings. The terms may be a relative concept and described based on directions expressed in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

It will be further understood that the meaning of terms such as “includes,” “including,” “include,” “comprises,” “comprise,” “comprising,” “has,” “have,” “having,” specifies a property, a fixed number, a step (e.g., act or task), an operation, an element, a component and/or a (e.g., any suitable) combination thereof, but does not exclude other properties, fixed numbers, steps, operations, elements, components and/or one or more (e.g., any suitable) combinations thereof.

In this specification, the phrase “directly arranged” may refer to that there is no layer, film, region, plate, and/or the like between a portion of the layer, film, region, plate, and/or the like and the other portion. For example, “directly arranged” may refer to being arranged without using an additional member such and an adhesion member between two layers or two members.

Unless otherwise defined, all terms (including chemical, technical and scientific terms) used herein have the same meaning as commonly understood by a person of ordinary skill in the art to which this invention belongs. In addition, terms such as those defined in commonly used dictionaries should be interpreted as having meanings consistent with their meanings in the context of the relevant technology, and unless explicitly defined, it should not be interpreted in an overly idealistic or overly formal sense.

Each of the features of the one or more suitable embodiments of the present disclosure may be combined or combined with each other, in part or in whole, and technically one or more suitable interlocking and driving are possible. Each embodiment may be implemented independently of each other or may be implemented together in an association.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

In this context, “consisting essentially of” indicates that any additional components will not materially affect the chemical, physical, optical or electrical properties of the semiconductor film.

Hereinafter, a display device and a display panel provided in the display device according to one or more embodiments of the present disclosure will be described with reference to the accompanying drawings.

### Display Device

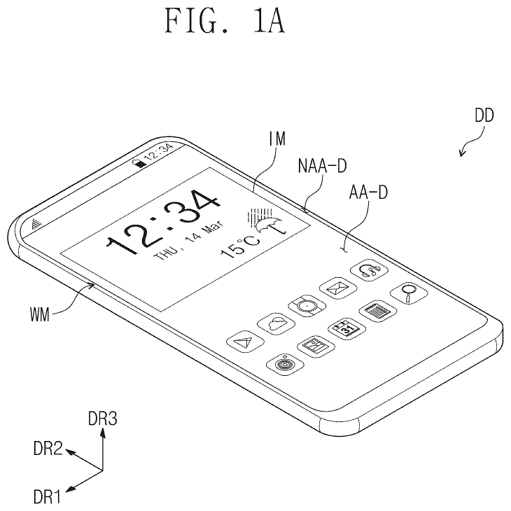

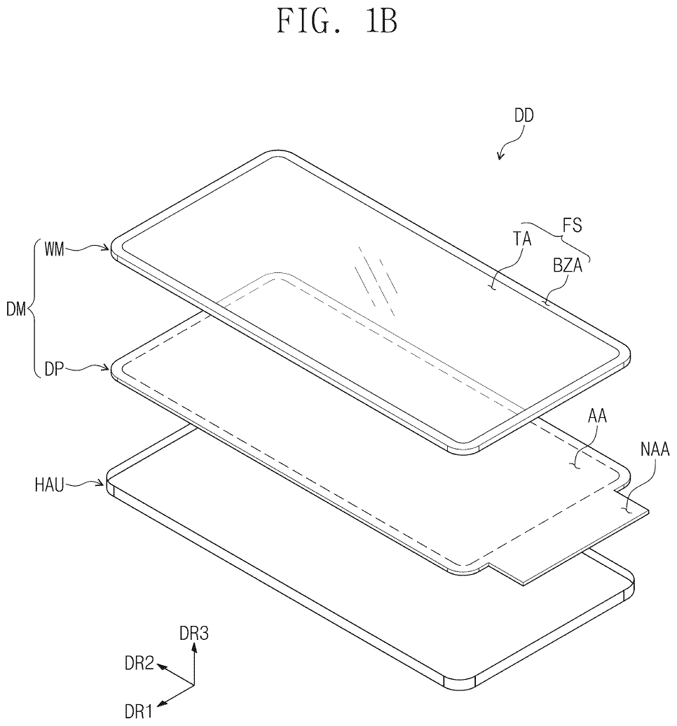

FIG. 1A is a perspective view of a display device according to one or more embodiments of the present disclosure. FIG. 1B is an exploded perspective view of the display device according to one or more embodiments of the present disclosure.

FIGS. 1A and 1B illustrate a mobile phone as an example of a display device DD according to one or more embodiments of the present disclosure.

In FIG. 1A and following drawings, first to third direction DR1 to DR3 are illustrated, and directions indicated by the first to third direction DR1, DR2, and DR3, which are described in this specification, may be converted to other directions as a relative concept. In this specification, the first direction DR1 and the second direction DR2 may be normal (e.g., perpendicular) to each other. A third direction DR3 may be a normal direction with respect to a plane defined by the first direction DR1 and the second direction DR2.

A thickness direction of the display device DD may be a direction that is parallel to the third direction DR3, which is the normal direction to the plane defined by the first direction DR1 and the second direction DR2. In this specification, a front (or top) surface and a rear (or bottom) surface of members constituting the electronic device DD may be defined based on the third direction DR3. In this specification, the phrases “on a/the plane” and “plan view” may refer to a plane parallel to the plane defined by the first direction DR1 and the second direction DR2, e.g., viewing a target portion from the top, and the phrase “on a/the cross-section” may refer to a plane parallel with the third direction DR3, e.g., viewing a cross-section formed by vertically cutting a target portion from the side.

The display device DD may display an image IM through an active area AA-

D. The active area AA-D may include a plane defined by the first direction DR1 and the second direction DR2. A peripheral area NAA-D is adjacent to the active area AA-D. The peripheral area NAA-D may be around (e.g., surround) the active area AA-D. However, the peripheral area NAA-D may be arranged adjacent to only one side of the active area AA-D or may not be provided.

The display device DD according to one or more embodiments may include a housing HAU and a display module DM. The display module DM according to one or more embodiments may include a display panel DP and a window member WM.

The window member WM may cover the entire outside of the display module DM. The window member WM may include a transmission area TA and a bezel area BZA. A front surface of the window member WM, which includes the transmission area TA and the bezel area BZA, may correspond to the front surface of the display device DD. The transmission area TA may correspond to the active area AA-D of the display device DD illustrated in FIG. 1A, and the bezel area BZA may correspond to the peripheral area NAA-D of the display device DD illustrated in FIG. 1A.

The transmission area TA may be an optically transparent area. The bezel area BZA may be an area having light transmittance that is relatively less than that of the transmission area TA. The bezel area BZA may have a set or predetermined color. The bezel area BZA may be arranged adjacent to the transmission area TA to be around (e.g., surround) the transmission area TA. However, the bezel area BZA may be arranged adjacent to only one side of the transmission area TA, or a portion thereof may not be provided.

The display panel DP may include an active area AA and a peripheral area NAA. The active area AA may be an area that is activated according to an electrical signal. In one or more embodiments, the active area AA may be an area on which the image IM (see FIG. 1A) is displayed. The active area AA of the display panel DP may correspond to the active area AA-D of the display device DD illustrated in FIG. 1A, and the peripheral area NAA of the display panel DP may correspond to the surrounding area (e.g., around) NAA-D of the display device DD illustrated in FIG. 1A. The transmission area TA may overlap at least a portion of the active area AA. The peripheral area NAA may be an area covered by the bezel area BZA.

In one or more embodiments, an input detection unit may be provided on the display panel DP. The input detection unit may detect an external input applied from outside. The external input may be a user's input. The user's input may include one or more suitable types (kinds) of external inputs such as a portion of user's body (e.g., finger), light, heat, a pen, a pressure, and/or the like. The input sensor may be arranged directly on the display panel DP or may be coupled to the display panel DP through a separate adhesive member.

In this specification, if (e.g., when) a component (or area, layer, portion, and/or the like) is referred to as being “directly arranged” on another component, it may refer to that no third component is arranged between the component and another component. For example, if (e.g., when) a component is “directly arranged” on another component, it may refer to that the component is “in contact with” (e.g., on) another component.

The housing HAU may accommodate the display panel DP, and/or the like. The housing HAU may be coupled to the window member WM.

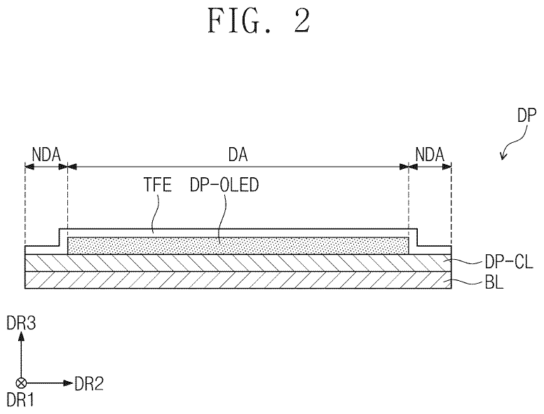

FIG. 2 is a cross-sectional view of a display panel according to one or more embodiments of the present disclosure. For example, FIG. 2 illustrates a cross-section of the display panel DP if (e.g., when) viewed in the first direction DR1.

Referring to FIG. 2, the display panel DP may include a base layer BL, a circuit layer DP-CL arranged on the base layer BL, a display element layer DP-OLED arranged on the circuit layer DP-CL, and a thin film encapsulation layer TFE arranged on the display element layer DP-OLED.

The base layer BL may include a display area DA and a non-display area NDA around the display area DA. The display area DA may correspond to the active area AA of the display panel DP in FIG. 1B, and the non-display area NDA may correspond to the peripheral area NAA of the display panel DP in FIG. 1B. The base layer BL may include a flexible plastic material such as polyimide (PI). The display element layer DP-OLED may be arranged on the display area DA.

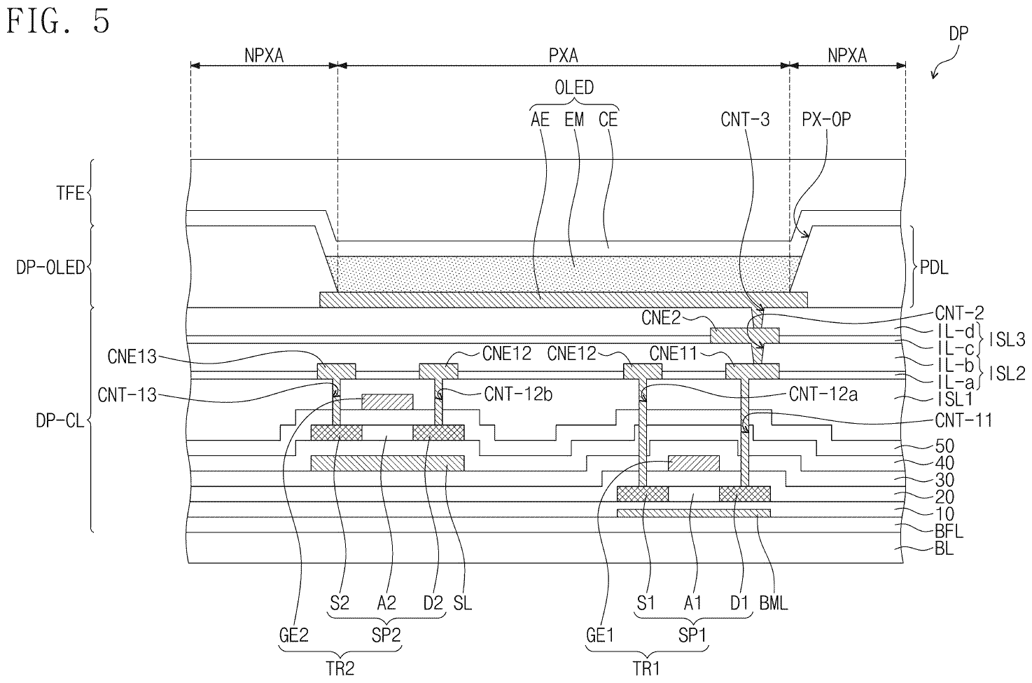

A plurality of pixels may be arranged on the circuit layer DP-CL and the display element layer DP-OLED. Each of the pixels may include transistors arranged on the circuit layer DP-CL and a light emitting element arranged on the display element layer DP-OLED and connected to the transistors. In some embodiments, each of the pixels may include connection electrodes CNE11, CNE12, CNE13, and CNE2 (see FIG. 5) that are electrically connected to the transistor. The configuration of the pixel is described in more detail elsewhere herein. That “the light emitting element is connected to the transistors” may refer to that the transistors are electrically connected to a first electrode AE (see FIG. 5) of the light emitting element.

The thin film encapsulation layer TFE may be arranged on the circuit layer DP-CL to cover the display element layer DP-OLED. The thin film encapsulation layer TFE may protect the pixels from moisture, oxygen, and external foreign substances.

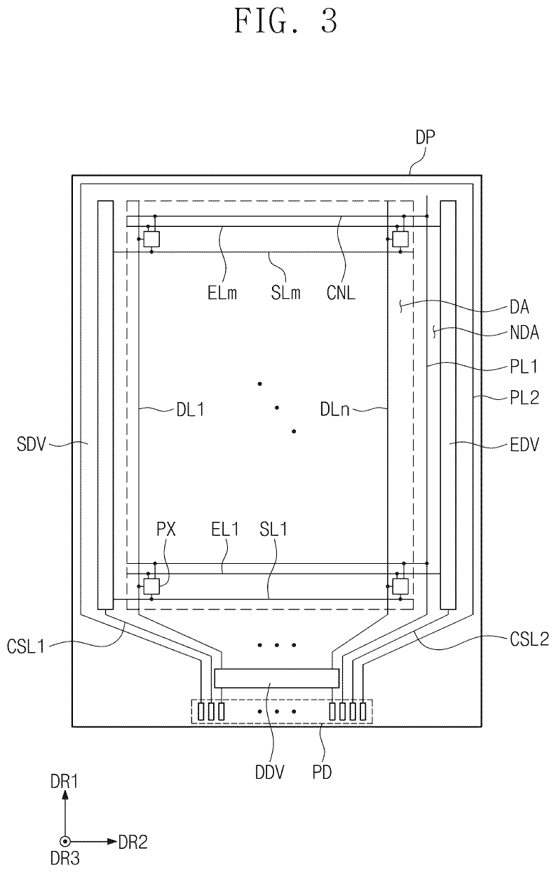

FIG. 3 is a plan view of the display panel according to one or more embodiments of the present disclosure.

Referring to FIG. 3, the display panel DP may include a scan driver SDV, a data driver DDV, an emission driver EDV, and a plurality of pads PD.

The display panel DP may have a rectangular shape with long sides extending in the first direction DR1 and short sides extending in the second direction

DR2, but the shape of the display panel DP is not limited thereto. The display panel DP may include a display area DA and a non-display area NDA around (e.g., surrounding) the display area DA.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, first and second power line layers PL1 and PL2, and connection lines CNL. Where m and n are natural numbers of (e.g., selected from among) at least 2 (e.g., or more).

The pixels PX may be arranged on the display area DA. Each of the scan driver SDV and the emission driver EDV may be arranged on the non-display area

NDA adjacent to each of the long sides of the display panel DP. The data driver DDV may be arranged on the non-display area NDA adjacent to one of the short sides of the display panel DP. When viewed from the plan view, the data driver DDV may be adjacent to a lower end of the display panel DP.

The scan lines SL1 to SLm may extend in the second direction DR2 and be connected to the pixels PX and the scan driver SDV. The data lines DL1 to DLn may extend in the first direction DR1 and be connected to the pixels PX and the data driver DDV. The emission lines EL1 to ELm may extend in the second direction DR2 and be connected to the pixels PX and the emission driver EDV.

The first power line PL1 may extend in the first direction DR1 and may be arranged on the non-display area NDA. The first power line PL1 may be arranged between the display area DA and the emission driver EDV.

The connection lines CNL may extend in the second direction DR2 and be arranged in the first direction DR1 and be connected to the first power line PL1 and the pixels PX. A first voltage may be applied to the pixels PX through the first power line PL1 and the connection lines CNL, which are connected to each other. The connection lines CNL may be substantially defined as portions of the first power line PL1 that receives the first voltage.

The second power line PL2 may be arranged on the non-display area NDA to extend along the long sides of the display panel DP and the other short side of the display panel DP, on which the data driver DDV is not arranged. The second power line PL2 may be arranged outside the scan driver SDV and the emission driver EDV.

In one or more embodiments, the second power line PL2 may extend toward the display area DA and be connected to the pixels PX. A second voltage having a level lower (e.g., less) than that of the first voltage may be applied to the pixels PX through the second power line PL2.

The first control line CSL1 may be connected to the scan driver SDV to extend toward a lower end of the display panel DP. The second control line CSL2 may be connected to the emission driver EDV to extend toward the lower end of the display panel DP. The data driver DDV may be arranged between the first control line CSL1 and the second control line CSL2.

The pads PD may be arranged on the non-display area NDA adjacent to the lower end of the display panel DP and may be closer to the lower end of the display panel DP than the data driver DDV. The data driver DDV, the first and second power lines PL1 and PL2, and the first and second control lines CSL1 and CSL2 may be connected to the pads PD. The data lines DL1 to DLn may be connected to the data driver DDV, and the data driver DDV may be connected to pads PD corresponding to the data lines DL1 to DLn.

In one or more embodiments, the display device DD (see FIG. 2) may further include a timing controller that controls operations of the scan driver SDV, the data driver DDV, and the emission driver EDV and a voltage generator that generates the first and second voltages. The timing controller and the voltage generator may be connected to the corresponding pads PD through a printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The emission driver EDV may generate a plurality of emission signals, and the emission signals may be applied to the pixels PX through the emission lines EL1 to ELm.

The pixels PX may receive the data voltages in response to the scan signals. The pixels PX may be to emit light having brightness corresponding the data voltages in response to the emission signals to display an image.

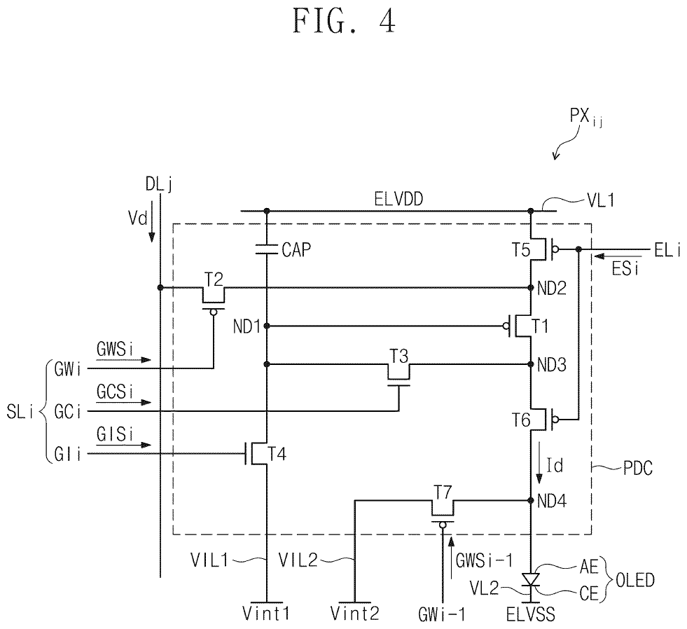

FIG. 4 is an equivalent circuit diagram of the pixel according to one or more embodiments of the present disclosure. For example, FIG. 4 illustrates an example of a pixel PXij connected to an i-th scan line SLi, an i-th emission line ELi, and a j-th data line DLj. Here, i and j represent natural numbers.

Referring to FIG. 4, the pixel PXij may include a light emitting element OLED and a pixel driving circuit PDC electrically connected to the light emitting element OLED. The pixel driving circuit PDC may include transistors T1 to T7 and a capacitor CAP. The transistors T1 to T7 and the capacitor CAP may control an amount of current flowing through the light emitting element OLED, and the light emitting element OLED may generate light having set or predetermined brightness according to the amount of received current.

The i-th scan line SLi may include i-th first to third scan lines GWi, GCi, and Gli. The first scan line GWi that receives an i-th write scan signal GWSi may be defined as a write scan line GWi. The second scan line GCi that receives an i-th compensation scan signal GCSi may be defined as a compensation scan line GCi.

The third scan line Gli that receives an i-th initialization scan signal GISi may be defined as an initialization scan line Gli.

The transistors T1 to T7 may include first to seventh transistors T1 to T7. Each of the first to seventh transistors T1 to T7 may include a source electrode, a drain electrode, and a gate electrode. Hereinafter, the source electrode may be referred to as a source, the drain electrode may be referred to as a drain, and the gate electrode may be referred to as a gate.

In this specification, “electrically connected between the transistor and the signal line or between the transistor and the transistor” may refer to that “the electrode of the transistor has an integral shape with the signal line or is connected through the connection electrode.”

Each of the first to seventh transistors T1 to T7 may be a transistor having an oxide semiconductor layer or a transistor having a low-temperature polycrystalline silicon (LTPS) semiconductor layer. Each of the first to seventh transistors T1 to T7 may be an N-type (kind) transistor or a P-type (kind) transistor. For example, each of the first, second, fifth, sixth, and seventh transistors T1, T2, T5, T6, and T7 may be a PMOS transistors having an LTPS semiconductor layer, and each of the third and fourth transistors T3 and T4 may be an NMOS transistor having an oxide semiconductor layer. However, the examples of the transistors T1 to T7 are not limited thereto. In some embodiments, although the pixel driving circuit PDC including the seven transistors T1 to T7 is illustrated as an example, the number of transistors included in the pixel driving circuit PDC is not limited thereto.

The light emitting element OLED may be defined as an organic light emitting element. The light emitting element OLED may include a first electrode AE and a second electrode CE. For example, the first electrode AE may be an anode, and the second electrode CE may be a cathode. The first electrode AE of the light emitting element OLED may be electrically connected to a first voltage line VL1 that receives a first driving voltage ELVDD. The second electrode CE of the light emitting element OLED may be electrically connected to a second voltage line VL2 that receives a second driving voltage ELVSS.

The first transistor T1 may be electrically connected between the first voltage line VL1 that receives the first driving voltage ELVDD and the light emitting element OLED. The first transistor T1 may include a source connected to a second node ND2, a drain connected to a third node ND3, and a gate connected to a first node ND1. The first transistor T1 may be turned on by a voltage of the first node ND1. The first transistor T1 may receive a data voltage Vd transmitted by a data line DLj according to a switching operation of the second transistor T2 to supply driving current Id to the light emitting element OLED. In one or more embodiments, the first transistor T1 may be defined as a driving transistor.

The second transistor T2 may be electrically connected between the data line DLj and the first transistor T1. The second transistor T2 may include a source connected to the data line DLj, a drain connected to the second node ND2, and a gate connected to the first scan line GWi. The second transistor T2 and the first transistor T1 may be connected through the second node ND2. The second transistor T2 may be turned on by the write scan signal GWSi applied through the first scan line GWi. The data voltage Vd applied to the data line DLj may be transmitted to the source of the first transistor T1 by the turned-on second transistor T2. In this embodiment, the second transistor T2 may be defined as a switching transistor.

The third transistor T3 may be electrically connected between the fourth transistor T4 and the first transistor T1. The third transistor T3 may include a source connected to the first node ND1, a drain connected to the third node ND3, and a gate connected to the second scan line GCi. The third transistor T3 and the first transistor T1 may be connected through the third node ND3. The third transistor T3 may be turned on by the compensation scan signal GCSi applied through the second scan line GCi. The gate of the first transistor T1 and the drain of the first transistor T1 may be electrically connected to each other by the turned-on third transistor T3, and the first transistor T1 may be diode-connected. In this embodiment, the third transistor T3 may be defined as a compensation transistor.

The fourth transistor T4 may be electrically connected between a first initialization line VIL1 that receives a first initialization voltage Vint1 and the third transistor T3. The fourth transistor T4 may include a source connected to the first initialization line VIL1, a drain connected to the first node ND1, and a gate connected to the third scan line Gli. The fourth transistor T4 may be turned on by the initialization scan signal GISi applied through the third scan line Gli. The first initialization voltage Vint1 may be transmitted to the first node ND1 by the turned-on fourth transistor T4, and a potential of the gate of the first transistor T1 may be initialized. In this embodiment, the fourth transistor T4 may be defined as an initialization transistor.

The fifth transistor T5 may be electrically connected between the first transistor T1 and the first voltage line VL1 that receives the first driving voltage ELVDD. The fifth transistor T5 may include a source connected to the first voltage line VL1, a drain connected to the second node ND2, and a gate connected to the emission line ELi.

The sixth transistor T6 may be electrically connected between the first transistor T1 and the light emitting element OLED. The sixth transistor T6 may include a source connected to the third node ND3, a drain connected to the first electrode AE of the light emitting element OLED through the fourth node ND4, and a drain connected to the emission line ELi.

The fifth transistor T5 and the sixth transistor T6 may be turned on by the emission signal ESi applied through the emission line ELi. An emission time of the light emitting element OLED may be controlled or selected by the emission signal ESi. When the fifth transistor T5 and the sixth transistor T6 are turned on, a driving current Id may be generated according to a voltage difference between the gate voltage of the gate of the first transistor T1 and the first driving voltage ELVDD, and the driving current Id may be supplied to the light emitting element OLED through the sixth transistor T6 so that the light emitting element OLED emits light. In one or more embodiments, the fifth transistor T5 and the sixth transistor T6 may be defined as emission control transistors.

The seventh transistor T7 may be electrically connected between the sixth transistor T6 and a second initialization line VIL2 that receives a second initialization voltage Vint2. The seventh transistor T7 may include a source connected to the fourth node ND4, a drain connected to the second initialization line VIL2, and a gate connected to the first scan line GWi-1. The gate of the seventh transistor T7 may be connected to an i-th write scan line GWi-1, which is a write scan line before the i-th write scan line GWi. However, one or more embodiments of the present disclosure is not limited thereto, and the gate of the seventh transistor T7 may be electrically connected to a separate fourth scan line.

The seventh transistor T7 may be turned on by an i-th write scan signal GWSi-1 applied through the first scan line GWi-1. The second initialization voltage Vint2 may be transmitted to the fourth node ND4 by the turned-on seventh transistor T7. The second initialization voltage Vint2 may have substantially the same level as the first initialization voltage Vint1, but the present disclosure is not limited thereto and may have a different level from the first initialization voltage Vint1. In this embodiment, the seventh transistor T7 may be defined as an initialization transistor.

The seventh transistor T7 may improve black expression ability of the pixel PXij. A portion of the driving current Id may be escaped through the seventh transistor T7 as a bypass current. When displaying a black image, current reduced by the amount of bypass current escaping from the driving current Id through the seventh transistor T7 may be provided to the light emitting element OLED, and thus, the black image may be clearly displayed. For example, an accurate black brightness image may be implemented through the seventh transistor T7, and a contrast ratio of the display device DD (see FIG. 1A) may be improved.

The capacitor CAP may include a first electrode receiving the first driving voltage ELVDD and a second electrode connected to the first node ND1. A charge corresponding to the voltage difference between the first electrode and the second electrode may be stored in the capacitor CAP. When the fifth transistor T5 and the sixth transistor T6 are turned on, an amount of current flowing in the first transistor T1 may be determined according to the voltage stored in the capacitor CAP.

The configuration of the pixel driving circuit PDC illustrated in FIG. 4 may be an example, and the configuration of the pixel driving circuit PDC may not be limited thereto and may be changed and implemented.

FIG. 5 is an enlarged cross-sectional view illustrating a portion of the display panel according to one or more embodiments of the present disclosure.

FIG. 5 illustrates an example of the light emitting element OLED and partial transistors of the pixel driving circuit PDC (see FIG. 4) connected to the light emitting element OLED. The preceding description may be applied to the configurations of the display panel DP illustrated in FIG. 5.

Referring to FIG. 5, the display panel DP may include a base layer BL, a circuit layer DP-CL, a display element layer DP-OLED, and an encapsulation layer TFE.

The base layer BL may provide a base surface on which the circuit layer DP-CL is arranged. The circuit layer DP-CL may include lower insulating layers BFL, and 10 to 50, first to third insulating layers ISL1, ISL2, and ISL3, transistors TR1 and TR2, and connection electrodes CNE11 to CNE13, and CNE2. The lower insulating layers BFL, and 10 to 50 may include a buffer layer BFL and first to fifth lower insulating layers 10 to 50 arranged on the buffer layer BFL. However, the lower insulating layers included in the circuit layer DP-CL are not limited thereto and may vary depending on the configuration of the pixel driver circuit included in the circuit layer DP-CL and the process of the circuit layer DP-CL.

The buffer layer BFL may be arranged on the base layer BL. The buffer layer BFL may include at least one inorganic layer. For example, the buffer layer BFL may include at least one of aluminum oxide, titanium oxide, silicon oxide, silicon nitride, silicon oxynitride, zirconium oxide, or hafnium oxide. The buffer layer BFL may improve bonding strength between a semiconductor pattern layer or a conductive pattern layer of the circuit layer DP-CL, which is arranged on the base layer BL, and the base layer BL.

Each of the first to fifth lower insulating layers 10 to 50 may include an inorganic layer and/or an organic layer and may have a single-layer or multi-layer structure. The inorganic layer may include at least one of aluminum oxide, titanium oxide, silicon oxide, silicon nitride, silicon oxynitride, zirconium oxide, or hafnium oxide. However, the material of the inorganic layer is not limited to the preceding examples. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin. However, the material of the organic layer is not limited to the preceding examples. In this specification, “a”-based resin refers to containing the “a” functional group.

A light blocking pattern BML may be arranged on the buffer layer BFL. When the buffer layer BFL is omitted, the light blocking pattern BML may be directly arranged on the base layer BL. The light blocking pattern BML may include molybdenum. The light blocking pattern BML may serve as a shielding function. The light blocking pattern BML may block an effect of an electrical potential to the transistors T1 to T7 (see FIG. 4) due to a polarization phenomenon between the insulating layers 10 to 50, ISL1, ISL2, and SIL3 arranged on the light blocking pattern BML of the transistors T1 to T7 (see FIG. 4).

FIG. 5 illustrates a first type (kind) transistor TR1 and a second type (kind) transistor TR2 of the pixel driving circuit PDC (see FIG. 4) as an example. In this embodiment, the first type (kind) transistor TR1 may be a silicon thin film transistor, and the second type (kind) transistor TR2 may be an oxide thin film transistor. The first type (kind) transistor TR1 may be one of the first, second, fifth, sixth, and seventh transistors T1, T2, T5, T6, and T7 described in FIG. 4, and the second type (kind) transistor TR2 may be one of the third and fourth transistors T3 and T4. In this embodiment, the first type (kind) transistor TR1 and the second type (kind) transistor TR2 may be arranged on different layers.

The semiconductor pattern (hereinafter, referred to as a first semiconductor pattern SP1) of the first type (kind) transistor TR1 may be arranged on the buffer layer BFL. The first semiconductor pattern SP1 may include a silicon semiconductor. For example, the silicon semiconductor may include amorphous silicon, polycrystalline silicon, and/or the like. For example, the first semiconductor pattern SP1 may include low-temperature polysilicon. However, if the first semiconductor pattern SP1 has semiconductor properties, the material included in the first semiconductor pattern SP1 is not limited to the preceding example.

FIG. 5 only illustrates a portion of the first semiconductor pattern SP1 arranged on the buffer layer BFL, and the first semiconductor pattern SP1 may be further arranged on other areas. The first semiconductor pattern SP1 may be arranged in a specific rule across the pixels PX (see FIG. 3). The first semiconductor pattern SP1 may have different electrical properties depending on whether the first semiconductor pattern SP1 is doped. The first semiconductor pattern SP1 may include a first region having high conductivity and a second region having low conductivity.

The first region may be doped with an N-type (kind) dopant or a P-type (kind) dopant. The P-type (kind) transistor may include a doped region doped with the P-type (kind) dopant, and the N-type (kind) transistor may include a doped region doped with the N- type (kind) dopant. The second region may be a non-doped region or a region doped at a lower concentration than that of the first region.

The conductivity of the first region may be greater than that of the second region, and the first region may substantially serve as an electrode or a signal line. The second region may substantially correspond to an active region (or channel) of the first type (kind) transistor TR1. For example, a portion of the first semiconductor pattern SP1 may be the active area of the first type (kind) transistor TR1, the other portion may be a source or drain of the first type (kind) transistor TR1, and another portion may be a connection electrode or a connection signal line.

The source region S1, the active region A1, and the drain region D1 of the first type (kind) transistor TR1 may be formed from the first semiconductor pattern SP1. The source region S1 and the drain region D1 may extend in opposite directions from the active region A1 in a cross-section.

The first lower insulating layer 10 may be arranged on the buffer layer BFL. The first lower insulating layer 10 may cover the light blocking pattern BML. The second lower insulating layer 20 may be arranged on the first lower insulating layer 10. The second lower insulating layer 20 may cover the first semiconductor pattern SP1.

The gate electrode (hereinafter, referred to as a first gate electrode GE1) of the first type (kind) transistor TR1 may be arranged on the second lower insulating layer 20. The first gate electrode GE1 may overlap the active area A1. In one or more embodiments, the first gate electrode GE1 may function as a mask in the process of doping the first semiconductor pattern SP1.

FIG. 5 illustrates an example in which the first type (kind) transistor TR1 has a top-gate structure in which the first gate electrode GE1 is arranged above the first semiconductor pattern SP1, but one or more embodiments of the present disclosure is not limited thereto. In one or more embodiments, the first type (kind) transistor TR1 may have a bottom-gate structure in which the first gate electrode GE1 is arranged below the first semiconductor pattern SP1.

The third lower insulating layer 30 may be arranged on the second lower insulating layer 20. The third lower insulating layer 30 may cover the first gate electrode GE1.

The scan line SL may be arranged on the third lower insulating layer 30. The scan line SL may correspond to a portion of the herein-described first to third scan lines GWi, GCi, and Gli (see FIG. 4).

The fourth lower insulating layer 40 may be arranged on the third lower insulating layer 30. The fourth lower insulating layer 40 may cover the scan line SL.

The semiconductor pattern (hereinafter, referred to as a second semiconductor pattern SP2) of the second type (kind) transistor TR2 may be arranged on the fourth lower insulating layer 40. The second semiconductor pattern SP2 may include an oxide semiconductor including metal oxide. The oxide semiconductor may include metal oxides such as zinc (Zn), indium (In), gallium (Ga), tin (Sn), and titanium (Ti), or metals such as zinc (Zn), indium (In), and gallium (Ga), tin (Sn), titanium (Ti), and/or a (e.g., any suitable) mixture (combination) of oxide thereof. The oxide semiconductors may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), zinc-tin oxide (ZTO), and/or the like. However, the example is not necessarily limited thereto.

The second semiconductor pattern SP2 may include a plurality of regions with different electrical properties depending on whether the metal oxide is reduced. In the second semiconductor patterns SP2, a region in which the metal oxide is reduced (hereinafter, referred to as a reduced region) may have greater conductivity than that of a region in which the metal oxide is not reduced (hereinafter, referred to as a non-reduced region). The reduction region may actually serve as the source or drain of the transistor. The non-reducing region may substantially correspond to the channel (or active) of the transistor.

The source region S2, the active region A2, and the drain region D2 of the second type (kind) transistor TR2 may be formed from the second semiconductor pattern SP2. The source region S2 and the drain region D2 may extend in opposite directions from the active region A2 in a cross-section.

The fifth lower insulating layer 50 may be arranged on the fourth lower insulating layer 40. The fifth lower insulating layer 50 may cover the second semiconductor pattern SP2.

The gate electrode (hereinafter, referred to as a second gate electrode GE2) of the second type (kind) transistor TR2 may be arranged on the fifth lower insulating layer 50. The second gate electrode GE2 may overlap the active area A2. In one or more embodiments, the second gate electrode GE2 may function as a mask in the process of doping the second semiconductor pattern SP2.

In one or more embodiments, the second semiconductor pattern SP2 may overlap a portion of the scan line SL arranged below the second semiconductor pattern SP2. The portion of the scan line SL overlapping the second semiconductor pattern SP2 may serve as a gate of the second type (kind) transistor TR2 together with the second gate electrode GE2. In this case, the gate of the second type (kind) transistor TR2 may be formed as a double gate to have a sufficient amount of gate charge and perform high-speed switching. In some embodiments, because the scan line SL is arranged to overlap the second semiconductor pattern SP2, the second semiconductor pattern SP2 may be prevented or reduced from being damaged by light introduced from a lower side of the display panel DP. However, the structure of the second type (kind) transistor TR2 is illustrative, and one or more embodiments of the present disclosure is not limited thereto.

The second semiconductor pattern SP2 of the second type (kind) transistor TR2 and the first semiconductor pattern SP1 of the first type (kind) transistor TR1 may be arranged on different layers. However, this is merely an example, and the semiconductor patterns of all the transistors included in the pixel driving circuit PDC (see FIG. 4) may be arranged on the same layer.

The first insulating layer ISL1 may be arranged on the fifth lower insulating layer 50. The first insulating layer ISL1 may cover the second gate electrode GE2.

The circuit layer DP-CL may include a plurality of first connection electrodes CNE11, CNE12, and CNE13. The plurality of first connection electrodes CNE11, CNE12, and CNE13 may be arranged on the first insulating layer ISL1. As illustrated in FIG. 5, the first connection electrodes CNE11, CNE12, and CNE13 may include first-1, first-2, and first-3 connection electrodes CNE11, CNE12, and CNE13. The first-1 to first-3 connection electrodes CNE11, CNE12, and CNE13 may be arranged to be spaced and/or apart (e.g., spaced apart or separated) from each other on the same layer of the first insulating layer ISL1.

The plurality of first connection electrodes CNE11, CNE12, and CNE13 may be electrically connected to the semiconductor patterns SP1 and SP2 through contact holes CNT-11, CNT-12a, CNT-12b, and CNT-13 defined in the first insulating layer ISL1. In this specification, the contact holes CNT-11, CNT-12a, CNT-12b, and CNT-13 defined in at least the first insulating layer ISL1 to connect the semiconductor patterns SP1 and SP2 to the first connection electrodes CNE11, CNE12, and CNE13 may be defined as first contact holes.

The first-1 connection electrode CNE11 may be connected to the drain region D1 of the first type (kind) transistor TR1. The first-1 connection electrode CNE11 may be connected to the drain region D1 through the contact hole CNT-11 passing through the second to fifth lower insulating layers 20 to 50 and the first insulating layer ISL1.

The first-2 connection electrode CNE12 may be connected to the first source region S1 of the first type (kind) transistor TR1. The first-2 connection electrode CNE12 may be connected to the first source region S1 through the contact hole CNT-12a passing through the second to fifth lower insulating layers 20 to 50 and the first insulating layer ISL1.

The first-2 connection electrode CNE12 may extend on a plane to overlap the drain region D2 of the second type (kind) transistor TR2. The first-2 connection electrode CNE12 may be connected to the drain region D2 through the contact hole CNT-12b passing through the fifth lower insulating layer 50 and the first insulating layer ISL1. Thus, the second semiconductor pattern SP2 of the second type (kind) transistor TR2 and the first semiconductor pattern SP1 of the first type (kind) transistor TR1, which are arranged on different layers, may be connected to each other through the first-2 connection electrode CNE12.

The first-3 connection electrode CNE13 may be connected to the second source region S2 of the second type (kind) transistor TR2. The first-3 connection electrode CNE13 may be connected to the second source region S2 through the contact hole CNT-13 passing through the fifth lower insulating layer 50 and the first insulating layer ISL1.

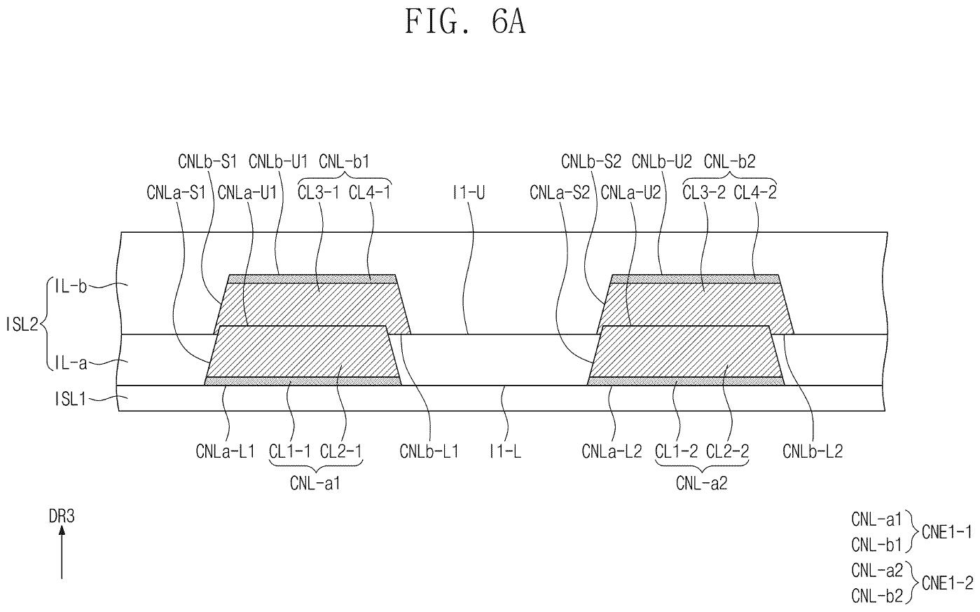

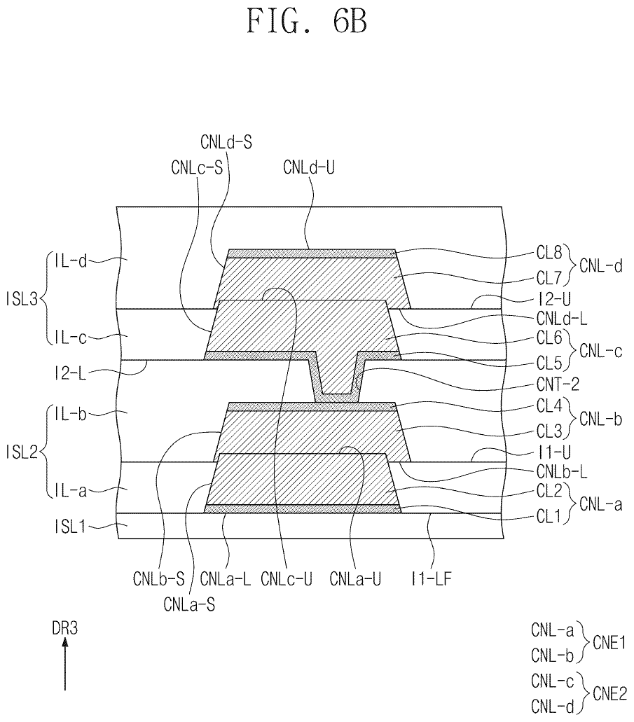

Each of the plurality of first connection electrodes CNE11, CNE12, and CNE13 may include first conductive layers CNL-a1 and CNL-a2 (see FIG. 6A), each of which includes aluminum, and second conductive layers CNL-b1 and CNL-b2 (see FIG. 6A) which are arranged on the first conductive layers CNL-a1 and CNL-a2 and each of which includes aluminum. Each of the first-1, first-2, and first-3 connection electrodes CNE11, CNE12, and CNE13 may include first conductive layer CNL-a1 and CNL-a2 (see FIG. 6A), each of which includes aluminum, and second conductive layers CNL-b1 and CNL-b2 (see FIG. 6A) which are arranged on the first conductive layers CNL-a1 and CNL-a2 and each of which includes aluminum. Details about the first conductive layers and the second conductive layers included in the plurality of first connection electrodes CNE11, CNE12, and CNE13 will be described in more detail later with reference to FIG. 6A.

The second insulating layer ISL2 may be arranged on the first insulating layer ISL1. The second insulating layer ISL2 may cover the plurality of first connection electrodes CNE11, CNE12, and CNE13. The second insulating layer ISL2 may cover the first-1 to first-3 connection electrodes CNE11, CNE12, and CNE13. The second insulating layer ISL2 may have a multilayer structure. For example, the second insulating layer ISL2 may have a two-layer structure made of different materials. In one or more embodiments, the second insulating layer ISL2 may include a first sub-insulating layer IL-a arranged on the first insulating layer ISL1, and a second sub-insulating layer IL-b arranged on the first sub-insulating layer IL-a. The first sub-insulating layer IL-a may be arranged between first conductive layers CNL-a1 and CNL-a2 (see FIG. 6A), which are described in more detail elsewhere herein. The second sub-insulating layer IL-b may be arranged on the first sub-insulating layer IL-a and may cover second conductive layers CNL-b1 and CNL-b2 (see FIG. 6A), which are described in more detail elsewhere herein.

In the display panel DP according to one or more embodiments of the present disclosure, each of the pixels may include a second connection electrode CNE2 arranged between each of the plurality of first connection electrodes CNE11, CNE12, and CNE13 and the display element layer DP-OLED and be electrically connected to at least a portion of the plurality of first connection electrodes CNE11, CNE12, and CNE13. The second connection electrode CNE2 may be arranged on the second insulating layer ISL2. In some embodiments, although not separately shown, a portion of the signal lines included in the display panel DP may be arranged on the second insulating layer ISL2.

The second connection electrode CNE2 may be connected to the first-1 connection electrode CNE11 through the contact hole CNT-2 passing through the second sub-insulating layer IL-b of the second insulating layer ISL2. The second connection electrode CNE2 may be connected to the drain region D1 of the first type (kind) transistor TR1 through the first-1 connection electrode CNE11. The first electrode AE of the light emitting element OLED and the first-1 connection electrode CNE11 may be connected to each other by the second connection electrode CNE2. In one or more embodiments, the first type (kind) transistor TR1 illustrated in FIG. 5 may correspond to the sixth transistor T6 connected to the first electrode AE in FIG. 4. The embodiment of the present disclosure is not limited thereto, and the second connection electrode CNE2 may not be provided, or an addition connection electrode arranged between the second connection electrode CNE2 and the first-1 connection electrode CNE11 may be further arranged inside the circuit layer DP-CL. In this specification, the contact hole CNE2 defined in at least the second insulating layer ISL2 to connect the first-1 connection electrode CNE11 to the second connection electrode CNE2 may be referred to as a second contact hole.

The second connection electrode CNE2 included in each of the plurality of pixels may include a third conductive layer CNL-c (see FIG. 6B) including aluminum and a fourth conductive layer CNL-d (see FIG. 6B) arranged on the third conductive layer CNL-c (see FIG. 6B) and including aluminum. Details about the third and fourth conductive layers included in the second connection electrode CNE2 are described in more detail elsewhere herein with reference to FIG. 6B.

The display panel DP according to one or more embodiments of the present disclosure may further include a third insulating layer ISL3 arranged on the second insulating layer ISL2. The third insulating layer ISL3 may cover the second connection electrode CNE2.

The third insulating layer ISL3 may have a multilayer structure. For example, the third insulating layer ISL3 may have a two-layer structure made of different materials. In one or more embodiments, the third insulating layer ISL3 may include a third sub-insulating layer IL-c arranged on the second insulating layer ISL2 and a fourth sub-insulating layer IL-d arranged on the third sub-insulating layer IL-c. The third sub-insulating layer IL-c may cover at least a portion of a side surface of the third conductive layer CNL-c (see FIG. 6B), which are described in more detail elsewhere herein. The fourth sub-insulating layer IL-d may be arranged on the third sub-insulating layer IL-c and may cover the fourth conductive layer CNL-d (see FIG. 6B), which are described in more detail elsewhere herein.

The display element layer DP-OLED may be arranged on the circuit layer DP-CL. The display device layer DP-OLED may include a pixel defining layer PDL and a light emitting element OLED. The light emitting element OLED may include a first electrode AE, an emission layer EM, and a second electrode CE.

The light emitting element OLED may include an organic light emitting element, a quantum dot light emitting element, a micro LED light emitting element, or a nano LED light emitting element. However, one or more embodiments of the present disclosure is not limited thereto, and the light emitting element OLED may include one or more suitable embodiments as long as light is generated, or an amount of light is controlled or selected according to an electrical signal.

The light emitting element OLED may be electrically connected to the transistor of the corresponding pixel driving circuit PDC (see FIG. 4). FIG. 5 illustrates an example in which the light emitting element OLED is electrically connected to the corresponding sixth transistor T6 (see FIG. 4).

The first electrode AE of the light emitting element OLED may be arranged on the uppermost layer of the circuit layer DP-CL. For example, the first electrode AE may be arranged on the third insulating layer ISL3. The first electrode AE may be connected to the second connection electrode CNE2 through the contact hole CNT-3 passing through the fourth sub-insulating layer IL-d. The first electrode AE may be electrically connected to the first type (kind) transistor TR1 through the corresponding second connection electrode CNE2 and the corresponding first-1 connection electrode CNE11.

The pixel defining layer PDL may be arranged on the uppermost layer of the circuit layer DP-CL. For example, the pixel defining layer PDL may be arranged on the third insulating layer ISL3. A light emitting opening PX-OP exposing a portion of the first electrode AE may be defined in the pixel defining layer PDL. The display area DA (see FIG. 3) of the display panel DP may include an emission area PXA and a non-emission area NPXA. In this embodiment, an area of the first electrode AE exposed by the light emitting opening PX-OP may correspond to the light emission area PXA. An area on which the pixel defining layer PDL is arranged may correspond to the non-emission area NPXA. On the plane, the non-emission area NPXA may be around (e.g., surround) the emission area PXA and set a boundary of the emission area PXA.

The pixel defining layer PDL may include a polymer resin. For example, the pixel defining layer PDL may include a polyacrylate-based resin or a polyimide-based resin. The embodiment of the present disclosure is not limited thereto, and the pixel defining layer PDL may further include an inorganic material.

The pixel defining layer PDL may further include a light absorbing material. For example, the pixel defining layer PDL may include a black coloring agent such as a black dye or a black pigment. For example, the black coloring agent may include carbon black, a metal such as chromium, or oxides thereof. However, one or more embodiments of the present disclosure is not necessarily limited thereto.

The emission layer EM may be arranged on the first electrode AE. The emission layer EM of the light emitting element OLED may be arranged to correspond to the light emitting opening PX-OP and may be provided in an emission pattern in which the plurality of light emitting elements are spaced and/or apart (e.g., spaced apart or separated) from each other on the plane. However, one or more embodiments of the present disclosure is not limited thereto, and in the plurality of light emitting elements, the emission layer EM may be provided as an integrated film and provided as a common layer. The emission layer EM may include an organic light emitting material and/or an inorganic light emitting material. For example, the emission layer EM may include a fluorescent material, a phosphorescent material, a metal organic complex light emitting material, or a quantum dot. The emission layer EM may be to emit color light having any one of red, green, and blue colors.

The second electrode CE may be arranged on the emission layer EM. The second electrode CE may overlap the emission area PXA and the non-emission area NPXA. The second electrode CE may be commonly arranged on the plurality of pixels PX (see FIG. 3) to provide a common voltage to the plurality of pixels PX (see FIG. 3).

The light emitting elements OLED may further include an emission control layer arranged between the first electrode AE and the second electrode CE. For example, the emission control layer may include a hole control layer arranged between the first electrode AE and the emission layer EM or an electronic control layer arranged between the emission layer EM and the second electrode CE. The hole control layer may include a hole injection layer, a hole transport layer, or an electron blocking layer, and the electron control layer may include an electron injection layer, an electron transport layer, or a hole blocking layer.

The encapsulation layer TFE may be arranged on the display element layer DP-OLED. The encapsulation layer TFE may seal the light emitting element OLED. The encapsulation layer TFE may include at least one thin film of an inorganic layer and an organic layer. In one or more embodiments, the encapsulation layer TFE may include inorganic layers and an organic layer arranged between the inorganic layers.

The inorganic film of the encapsulation layer TFE may protect the light emitting elements OLED from moisture and/or oxygen. The inorganic film may include at least one of aluminum oxide, titanium oxide, silicon oxide, silicon nitride, silicon oxynitride, zirconium oxide, or hafnium oxide. However, the material of the inorganic film is not limited to the preceding examples.

The organic film of the encapsulation layer TFE may protect the light emitting element OLED from foreign substances such as dust particles. The organic film may include an acrylic resin. However, the material of the organic film is not limited to the preceding examples.

FIG. 6A is a cross-sectional view illustrating a portion of a configuration of the display panel according to one or more embodiments of the present disclosure. FIG. 6A illustrates shapes of the first insulating layer ISL1, a portion of the plurality of first connection electrodes arranged on the first insulating layer ISL1 in the circuit layer DP-CL of the display panel DP illustrated in FIG. 5, and the second insulating layer ISL2 that covers the plurality of first connection electrodes. In FIG. 6A, the first contact hole defined in the first insulating layer ISL1 may not be provided for convenience of explanation. When describing the first connection electrode according to one or more embodiments with reference to FIG. 6A, the same/similar reference numerals may be used for components that may each independently be the same/similar to those described in FIGS. 1A to 5, and duplicated descriptions thereof may not be provided.

Referring to FIG. 6A, the display panel DP according to one or more embodiments of the present disclosure may include a plurality of first connection electrodes CNE1-1 and CNE1-2. The plurality of first connection electrodes CNE1-1 and CNE1-2 may include a first-1 sub-connection electrode CNE1-1 and a first-2 sub-connection electrode CNE1-2. The first-1 and first-2 sub connection electrodes CNE1-1 and CNE1-2 may correspond to two first connection electrodes arranged to be adjacent to each other among the plurality of first connection electrodes illustrated in FIG. 5. For example, the first-1 sub-connection electrode CNE1-1 may correspond to the first-2 connection electrode CNE12 connected to the source region S1 of the first semiconductor pattern SP1, and the first-2 sub-connection electrode CNE1-2 may correspond to the first-1 connection electrode CNE11 connected to the drain region D1 of the second semiconductor pattern SP1, but are not limited thereto.

Referring to FIG. 6A, each of the plurality of first connection electrodes CNE1-1 and CNE1-2 may include first conductive layers CNL-a1 and CNL-a2 and second conductive layers CNL-b1, and CNL-b2, which are sequentially laminated. For example, the first-1 sub-connection electrode CNE1-1 may include a first-1 conductive layer CNL-a1 and a second-1 conductive layer CNL-b1, which are sequentially laminated, and the first-2 sub-connection electrode CNE1-2 may include a first-2 conductive layer CNL-a2 and a second-2 conductive layer CNL-b2, which are sequentially laminated. Each of the plurality of first connection electrodes CNE1-1 and CNE1-2 may include one electrode having a structure in which the first conductive layers CNL-a1 and CNL-a2 and the second conductive layers CNL-b1 and CNL-b2 are laminated.

The first conductive layers CNL-a1 and CNL-a2, which are included in the plurality of first connection electrodes CNE1-1 and CNE1-2, respectively, may be arranged on the same layer. For example, each of the first-1 conductive layer CNL-a1 and the first-2 conductive layer CNL-a2 may be arranged on the first insulating layer ISL1. Each of the first-1 conductive layer CNL-a1 and the first-2 conductive layer CNL-a2 may have substantially the same thickness. However, one or more embodiments of the present disclosure is not limited thereto.

Each of the first conductive layers CNL-a1 and CNL-a2 may include first layers CL1-1 and CL1-2 and second layers CL2-1 and CL2-2 arranged on the first layers CL1-1 and CL1-2. For example, the first-1 conductive layer CNL-a1 may include a first-1 layer CL1-1 arranged on the first insulating layer ISL1 and a second-1 layer CL2-1 arranged on the first-1 layer CL1-1, and the first-2 conductive layer CNL-a2 may include a first-2 layer CL1-2 arranged on the first insulating layer ISL1 and a second-2 layer CL2-2 arranged on the first-2 layer CL1-2.

Each of the first layers CL1-1 and CL1-2 and the second layers CL2-1 and CL2-2 may include a metal material. The first layers CL1-1 and CL1-2 and the second layers CL2-1 and CL2-2 may include different metal materials. In one or more embodiments, each of the first layers CL1-1 and CL1-2 may include titanium, and each of the second layers CL2-1 and CL2-2 may include aluminum.

In one or more embodiments, a thickness of each of the second layers CL2-1 and CL2-2 may be greater than that of each of the first layers CL1-1 and CL1-2. The thickness of the second-1 layer CL2-1 may be greater than that of the first-1 layer CL1-1. The thickness of the second-2 layer CL2-2 may be greater than that of the first-2 layer CL1-2.

The second layers CL2-1 and CL2-2 included in the first conductive layers CNL-a1 and CNL-a2 may correspond to the uppermost layer in the first conductive layers CNL-a1 and CNL-a2. The second layer CL2-1 and CL2-2 may be a layer arranged at the uppermost side of the layers included in the first conductive layers CNL-a1 and CNL-a2. A top surface of each of the first conductive layers CNL-a1 and CNL-a2 may be defined by a top surface of each of the second layers CL2-1 and CL2-2.

Each of the plurality of first connection electrodes CNE1-1 and CNE1-2 may include second conductive layers CNL-b1 and CNL-b2 arranged on the first conductive layers CNL-a1 and CNL-a2. The second conductive layers CNL-b1 and CNL-b2 may be directly arranged on the first conductive layers CNL-a1 and CNL-a2, respectively. The second-1 conductive layer CNL-b1 may be arranged on the first-1 conductive layer CNL-a1. The second-1 conductive layer CNL-b1 may be directly arranged on the first-1 conductive layer CNL-a1. A bottom surface of the second-1 conductive layer CNL-b1 may be in contact with the first-1 conductive layer CNL-a1. The second-2 conductive layer CNL-b2 may be arranged on the first-2 conductive layer CNL-a2. The second-2 conductive layer CNL-b2 may be directly arranged on the first-2 conductive layer CNL-a2. A bottom surface of the second-2 conductive layer CNL-b2 may be in contact with the first-2 conductive layer CNL-a2. The second-1 conductive layer CNL-b1 and the second-2 conductive layer CNL-b2 may have substantially the same thickness, but the present disclosure is not limited thereto.

Each of the second conductive layers CNL-b1 and CNL-b2 may include third layers CL3-1 and CL3-2 arranged on the first conductive layers CNL-a1 and CNL-a2, and fourth layers CL4-1 and CL4-2 arranged on the third layers CL3-1 and CL3-2. For example, the second-1 conductive layer CNL-b1 may include a third-1 layer CL3-1 arranged on the first-1 conductive layer CNL-a1 and a fourth-1 layer CL4-1 arranged on the third-1 layer CL3-1, and the second-2 conductive layer CNL-b2 may include a third-2 layer CL3-2 arranged on the first-2 conductive layer CNL-a2 and a fourth-2 layer CL4-2 arranged on the third-2 layer CL3-2.

The third layers CL3-1 and CL3-2 included in the second conductive layers CNL-b1 and CNL-b2 may corresponds to the lowermost layers in the second conductive layers CNL-b1 and CNL-b2. The third layer CL3-1 and CL3-2 may be layers arranged on the lowermost layer of the layers included in the second conductive layers CNL-b1 and CNL-b2. A bottom surface of each of the second conductive layers CNL-b1 and CNL-b2 may be defined by a bottom surface of each of the third layers CL3-1 and CL3-2.

Each of the third layers CL3-1 and CL3-2 and the fourth layers CL4-1 and CL4-2 may include a metal material. The third layers CL3-1 and CL3-2 and the fourth layers CL4-1 and CL4-2 may include different metal materials. In one or more embodiments, each of the third layers CL3-1 and CL3-2 may include aluminum, and each of the fourth layers CL4-1 and CL4-2 may include titanium. In one or more embodiments, the second layers CL2-1 and CL2-2 included in the first conductive layers CNL-a1 and CNL-a2 and the third layers CL3-1 and CL3-2 included in the second conductive layers CNL-b1 and CNL-b2 may include substantially the same materials. Each of the second layers CL2-1 and CL2-2 and the third layers CL3-1 and CL3-2 may include aluminum.

In one or more embodiments, a thickness of each of the third layers CL3-1 and CL3-2 may be greater than that of each of the fourth layers CL4-1 and CL4-2. A thickness of the third-1 layer CL3-1 may be greater than that of the fourth-1 layer CL4-1. A thickness of the third-2 layer CL3-2 may be greater than that of the fourth-2 layer CL4-2.

The third layers CL3-1 and CL3-2 may be directly arranged on the corresponding second layers CL2-1 and CL2-2, respectively. The third-1 layer CL3-1 may be directly arranged on the second-1 layer CL2-1. The third-2 layer CL3-2 may be directly arranged on the second-2 layer CL2-2. The second layers CL2-1 and CL2-2 may be a layer that is in direct contact with the bottom surface of each of the third layers CL3-1 and CL3-2. Each of the plurality of first connection electrodes CNE1-1 and CNE1-2 may include one electrode having a four-layer structure in which the first layers CL1-1 and CL1-2, the second layers CL2-1 and CL2-2, the third layers CL3-1 and CL3-2, and the fourth layers CL4-1 and CL4-2 are laminated. In FIG. 6A, a boundary between each of the second layers CL2-1 and CL2-2 and each of the third layers CL3-1 and CL3-2 may be clearly shown as a straight line, but is merely as an example, and the boundary between each of the second layers CL2-1 and CL2-2 and each of the third layers CL3-1 and CL3-2 may be unclearly shown in the cross-section.

The thickness of each of the second layers CL2-1 and CL2-2 and the thickness of each of the third layers CL3-1 and CL3-2 may be substantially the same. The thickness of the second-1 layer CL2-1 and the thickness of the third-1 layer CL3-1 may be substantially the same, and the thickness of the second-2 layer CL2-2 and the thickness of the 3-2 layer CL3-2 may be the same. However, one or more embodiments of the present disclosure is not limited thereto. The thickness of each of the second layers CL2-1 and CL2-2 and the thickness of each of the third layers CL3-1 and CL3-2 may be different from each other.

In one or more embodiments, the sum (e.g., total) of the thicknesses of the second layers CL2-1 and CL2-2 and the third layers CL3-1 and CL3-2 may be at least about 10,000 angstrom (Å) (e.g., or more) and at most about 16,000 Å (e.g., or less). For example, the sum (e.g., total) of the thickness of the second-1 layer CL2-1 and the thickness of the third-1 layer CL3-1 may be at least about 10,000 Å (e.g., or more) and at most about 16,000 Å (e.g., or less). The sum (e.g., total) of the thickness of the second-2 layer CL2-2 and the thickness of the 3-2 layer CL3-2 may be at least about 10,000 Å (e.g., or more) and at most about 16,000 Å (e.g., or less). When the sum (e.g., total) of the thicknesses of the second layer CL2-1 and CL2-2 and the thicknesses of the third layer CL3-1 and CL3-2 is less than about 10,000 Å, a desired or suitable resistance reduction effect of the first connection electrodes CNE1-1 and CNE1-2 may not be expected, and if (e.g., when) the sum (e.g., total) of the thicknesses of the second layers CL2-1 and CL2-2 and the thicknesses of the third layers CL3-1 and CL3-2 exceeds about 16,000 Å, the thickness of each of the first connection electrodes CNE1-1 and CNE1-2 may become excessively (or substantially) thick, making it difficult to miniaturize the display device. As the sum (e.g., total) of the thicknesses of the second layer CL2-1 and CL2-2 and the thicknesses of the third layer CL3-1 and CL3-2 satisfies the herein-mentioned range, resistance of the electrode may be effectively reduced, and an occurrence of electrode defects in the process may be reduced to improve process reliability. Conductivity of the second layers CL2-1 and CL2-2 and the third layers CL3-1 and CL3-1 may substantially determine conductivity of the first connection electrodes CNE1-1 and CNE1-2. The larger the sum (e.g., total) of the thicknesses of the second layers CL2-1 and CL2-2 and the third layers CL3-1 and CL3-2, the lower the resistance of the first connection electrodes CNE1-1 and CNE1-2. Thus, the display panel DP (FIG. 1B) may be driven at a high speed, the display characteristics of the display panel DP (FIG. 1B) may be improved, and power consumption may be reduced.

For example, when the combined thickness of the second layers (CL2-1 and CL2-2) and the third layers (CL3-1 and CL3-2) is less than about 10,000 Å, the first connection electrodes (CNE1-1 and CNE1-2) may not achieve the desired resistance reduction. Conversely, if this combined thickness exceeds about 16,000 Å, the first connection electrodes may become too thick, complicating the miniaturization of the display device. Maintaining the combined thickness within this range effectively reduces electrode resistance and minimizes defects during the manufacturing process, thereby enhancing process reliability. The conductivity of the second and third layers significantly influences the conductivity of the first connection electrodes. Increasing the combined thickness of these layers lowers the resistance of the first connection electrodes, enabling high-speed operation, improved display characteristics, and reduced power consumption for the display panel (DP, FIG. 1B).

The second insulating layer ISL2 may be arranged on the first insulating layer ISL1 to cover the plurality of first connection electrodes CNE1-1 and CNE1-2. The second insulating layer ISL2 may include a first sub-insulating layer IL-a arranged on the first insulating layer ILS1 and a second sub-insulating layer IL-b arranged on the first sub-insulating layer IL-a. In one or more embodiments, the first sub-insulating layer IL-a may be arranged between the adjacent first conductive layers CNL-a1 and CNL-a2. The first sub-insulating layer IL-a may be arranged between the first conductive layers CNL-a1 and CNL-a2 to fill a space between the first conductive layers CNL-a1 and CNL-a2.

The first sub-insulating layer IL-a may be arranged between the first conductive layers CNL-a1 and CNL-a2 and be in contact with each of the first conductive layers CNL-a1 and CNL-a2. The first sub-insulating layer IL-a may be arranged between the first conductive layers CNL-a1 and CNL-a2 to cover at least a portion of side surfaces CNLa-S1 and CNLa-S2 of each of the first conductive layers CNL-a1 and CNL-a2. The first sub-insulating layer IL-a may cover each of a first-1 electrode side surface CNLa-S1 of the first-1 conductive layer CNL-a1 and a first-2 electrode side surface CNLa-S2 of the first-2 conductive layer CNL-a2. The first sub-insulating layer IL-a may be in contact with each of the first-1 electrode side surface CNLa-S1 of the first-1 conductive layer CNL-a1 and the first-2 electrode side surface CNLa-S2 of the first-2 conductive layer CNL-a2.

The first sub-insulating layer IL-a may be in contact with each of the first layers CL1-1 and CL1-2 and the second layers CL2-1 and CL2-2 of the first conductive layers CNL-a1 and CNL-a2. The first sub-insulating layer IL-a may be in contact with the side surface of each of the first conductive layers CNL-a1 and CNL-a2 to cover at least a portion of the side surface of each of the first layers CL1-1 and CL1-2 and the second layers CL2-1 and CL2-2. In one or more embodiments, the first sub-insulating layer IL-a may entirely cover the side surfaces of the first layers CL1-1 and CL1-2 and may cover a portion of the side surfaces of the second layers CL2-1 and CL2-2.

The first sub-insulating layer IL-a may not be arranged on top surfaces CNLa-U1 and CNLa-U2 of the first conductive layers CNL-a1 and CNL-a2. The first sub-insulating layer IL-a may be arranged to be in contact with each of only the side surfaces CNLa-S1 and CNLa-S2 of the first conductive layers CNL-a1 and CNL-a2 and may not be in contact with each of the top surfaces CNLa-U1 and CNLa-U2 of the first conductive layers CNL-a1 and CNL-a2. The first sub-insulating layer IL-a may not be arranged on all of the first-1 electrode top surface CNLa-U1 of the first-1 conductive layer CNL-a1 and the first-2 electrode top surface CNla-U2 of the first-2 conductive layer CNL-a2. The first sub-insulating layer IL-a may not be arranged on the top surfaces CNLa-U1 and CNLa-U2 of the first conductive layers CNL-a1 and CNL-a2, but may expose the top surfaces CNLa-U1 and CNLa-U2 of the first conductive layers CNL-a1 and CNL-a2 so that the second conductive layers CNL-b1 and CNL-b2 are directly arranged on the top surfaces CNLa-U1 and CNLa-U2 of the first conductive layers CNL-a1 and CNL-a2.

The top surface I1-U of the first sub-insulating layer IL-a may be arranged lower the top surfaces CNLa-U1 and CNLa-U2 of the first conductive layers CNL-a1 and CNL-a2. For example, the top surface I1-U of the first sub-insulating layer IL-a may be defined to be further adjacent to the first insulating layer ISL1 than the top surfaces CNLa-U1 and CNLa-U2 of the first conductive layers CNL-a1 and CNL-a2. The top surface I1-U of the first insulating layer ISL1 may be arranged below the first-1 electrode top surface CNLa-U1 of the first-1 conductive layer CNL-a1 and the first-2 electrode top surface CNLa-U2 of the first-2 conductive layer CNL-a2.

The top surface I1-U of the first sub-insulating layer IL-a may have a flat shape. The top surface I1-U of the first sub-insulating layer IL-a may be parallel to the top surfaces CNLa-U1 and CNLa-U2 of the first conductive layers CNL-a1 and CNL-a2. The top surface I1-U of the first sub-insulating layer IL-a may be parallel to each of the first-1 electrode top surface CNLa-U1 of the first-1 conductive layer CNL-a1 and the first-2 electrode top surface CNLa-U2 of the first-2 conductive layer CNL-a2.

However, one or more embodiments is not limited thereto, and the top surface I1-U of the first sub-insulating layer IL-a may have a curved shape. The top surface I1-U of the first sub-insulating layer IL-a may be arranged below the top surfaces CNLa-U1 and CNLa-U2 of the first conductive layers CNL-a1 and CNL-a2 and may have a curved shape that is recessed to be adjacent to the first insulating layer ISL1. For example, as the top surface I1-U of the first sub-insulating layer IL-a is gradually away from the top surfaces CNLa-U1 and CNLa-U2 of the first conductive layers CNL-a1 and CNL-a2, the top surface I1-US may have a curved shape that is recessed to be adjacent to the first insulating layer ISL1.

The first sub-insulating layer IL-a may fill a space defined between the first conductive layers CNL-a1 and CNL-a2. The first sub-insulating layer IL-a may fill at least a portion of the space defined between the first conductive layers CNL-a1 and CNL-a2. The first sub-insulating layer IL-a may cover the entire side surface of the first layers CL1-1 and CL1-2 of the first conductive layers CNL-a1 and CNL-a2 and a portion of the second layer (CL2-1 and CL2-2 and may fill the space defined between the first conductive layers CNL-a1 and CNL-a2. However, one or more embodiments is not limited thereto, and the first sub-insulating layer IL-a may fully fill a space defined between the first conductive layers CNL-a1 and CNL-a2. For example, the first sub-insulating layer IL-a may entirely cover the side surface of each of the first layers CL1-1 and CL1-2 and the second layers CL2-1 and CL2 of the first conductive layers CNL-a1 and CNL-a2 and may fully fill a space between the first conductive layers CNL-a1 and CNL-a2 so that the top surface I1-U of the first sub-insulating layer IL-a is parallel to the top surfaces CNLa-U1 and CNLa-U2 of the first conductive layers CNL-a1 and CNL-a2.

The first sub-insulating layer IL-a may include a first organic material and a first inorganic material. The first inorganic material included in the first sub-insulating layer IL-a may be an inorganic material containing silicon. The first inorganic material included in the first sub-insulating layer IL-a may include at least one of silicon dioxide (SiO₂), silicon nitride (Si₃N₄), or silicon oxynitride (SiON). For example, the first inorganic material may be silicon dioxide (SiO₂). The first organic material included in the first sub-insulating layer IL-a may include at least one of siloxane, polyimide, or an acrylic polymer. The first organic material may be, for example, siloxane. The first sub-insulating layer IL-a may be made of a first inorganic material and a first organic material.

With respect to the first organic material and the first inorganic material included in the first sub-insulating layer IL-a, a content (e.g., amount) of the first inorganic material may be greater than that of the first organic material compared to the total content (e.g., amount) of the first sub-insulating layer IL-a. The content (e.g., amount) of the first organic material compared to the total content (e.g., amount) of the first sub-insulating layer IL-a may be about 10 wt % or more and less than about 50 wt %. When the content (e.g., amount) of the first organic material in the first sub-insulating layer IL-a is less than about 10 wt %, a coating property of a filling material may decrease in the process of forming the first sub-insulating layer IL-a, and thus, the first sub-insulating layer IL-a may not be arranged only between the first conductive layers CNL-a1 and CNL-a2, but be arranged on the top surfaces CNLa-U1 and CNLa-U2 of the first conductive layers CNL-a1 and CNL-a2. When the content (e.g., amount) of the first organic material in the first sub-insulating layer IL-a is about 50 wt % or more, the first sub-insulating layer IL-a may not be patterned to be arranged only between the first conductive layers CNL-a1 and CNL-a2.

The first sub-insulating layer IL-a may be arranged on the same layer as the first conductive layers CNL-a1 and CNL-a2. The first sub-insulating layer IL-a and the first conductive layers CNL-a1 and CNL-a2 may be arranged on the first insulating layer ISL1. The first sub-insulating layer IL-a may cover a portion of the top surface of the first insulating layer ISL1, which is exposed because the first conductive layers CNL-a1 and CNL-a2 are not arranged. The bottom surface 11-L of the first sub-insulating layer IL-a may define one surface arranged on the same layer as and aligned with each of the bottom surfaces CNLa-L1 and CNLa-L2 of the first conductive layers CNL-a1 and CNL-a2. The bottom surface 11-L of the first sub-insulating layer IL-a may define one surface aligned with each of the first-1 electrode bottom surface CNLa-L1 of the first-1 conductive layer CNL-a1 and the first-2 electrode bottom surface CNLa-L2 of the first-2 conductive layer CNL-a2.

At least a portion of the bottom surface of each of the second conductive layers CNL-b1 and CNL-b2 may be in contact with the first sub-insulating layer IL-a. The bottom surfaces of the second conductive layers CNL-b1 and CNL-b2 corresponding to edges of the second conductive layers CNL-b1 and CNL-b2 may be in contact with the first sub-insulating layer IL-a. At least a portion of the bottom surface of each of the second-1 conductive layer CNL-b1 and the second-2 conductive layer CNL-b2 may be in contact with the first sub-insulating layer IL-a.

The side surfaces CNLa-S1 and CNLa-S2 of the first conductive layers CNL-a1 and CNL-a2 may be misaligned with the side surfaces CNLb-S1 and CNLb-S2 of the second conductive layers CNL-b1 and CNL-b2. The top surfaces CNLa-U1 and CNLa-U2 of the first conductive layers CNL-a1 and CNL-a2 may be misaligned with the bottom surfaces CNLb-L1 and CNIb-L2 of the second conductive layers CNL-b1 and CNL-b2. The first-1 electrode side surface CNLa-S1 of the first-1 conductive layer CNL-a1 may be misaligned with the second-1 electrode side surface CNLb-S1 of the second-1 conductive layer CNL-b1. The first-2 electrode side surface CNLa-S2 of the first-2 conductive layer CNL-a2 may be misaligned with the second-2 electrode side surface CNLb-S2 of the second-2 conductive layer CNL-b2.

At least a portion of each of the top surfaces CNLa-U1 and CNLa-U2 of the first conductive layers CNL-a1 and CNL-a2 may be in contact with the second conductive layers CNL-b1 and CNL-b2. The second layers CL2-1 and CL2-2 included in the first conductive layers CNL-a1 and CNL-a2 may be in contact with the corresponding second conductive layers CNL-b1 and CNL-b2. The second-1 layer CL2-1 of the first-1 conductive layer CNL-a1 may be in contact with the second-1 conductive layer CNL-b1, and the second-2 layer CL2-2 of the first-2 conductive layer CNL-a2 may be in contact with the second-2 conductive layer CNL-b2.

A planar area of each of the top surfaces CNLa-U1 and CNLa-U2 of the first conductive layers CNL-a1 and CNL-a2 may be less than that of each of the bottom surface CNLb-L1 and CNLb-L2 of the second conductive layers CNL-b1 and CNL-b2. A planar area of the first-1 electrode top surface CNLa-U1 of the first-1 conductive layer CNL-a1 may be less than that of the first-1 electrode bottom surface CNLb-L1 of the second-1 conductive layer CNL-b1. A planar area of the first-2 electrode top surface CNLa-U2 of the first-2 conductive layer CNL-a2 may be less than that of the second-2 electrode bottom surface CNLb-L2 of the second-2 conductive layer CNL-b2. A planar area of each of the bottom surfaces CNLb-L1 and CNLb-L2 of the second conductive layers CNL-b1 and CNL-b2 may be greater than that of each of the top surfaces CNLa-U1 and CNLa-U2 of the first conductive layers CNL-a1 and CNL-a2, and each of the top surfaces CNLa-U1 and CNLa-U2 of the first conductive layers CNL-a1 and CNL-a2 may be fully covered by the second conductive layers CNL-b1 and CNL-b2. However, one or more embodiments of the present disclosure is not limited thereto.

The second sub-insulating layer IL-b may be arranged on the first sub-insulating layer IL-a to cover the second conductive layers CNL-b1 and CNL-b2. The second sub-insulating layer IL-b may cover each of the second conductive layers CNL-b1 and CNL-b2 and may be in contact with each of the second conductive layers CNL-b1 and CNL-b2. The second sub-insulating layer IL-b may cover the side surfaces CNLb-S1 and CNLb-S2 and the top surfaces CNLb-U1 and CNLb-U2 of the second conductive layers CNL-b1 and CNL-b2. The second sub-insulating layer IL-b may cover each of the second-1 electrode side surface CNLb-S1 and the second-1 electrode top surface CNLb-U1 of the second-1 conductive layer CNL-b1 and the second-2 electrode side surface CNLb-S2 and the second-2 electrode top surface CNLb-U2 of the second-2 conductive layer CNL-b2.

The second sub-insulating layer IL-b may be in contact with each of the third layers CL3-1 and CL3-2 and the fourth layers CL4-1 and CL4-2 of the second conductive layers CNL-b1 and CNL-b2. The second sub-insulating layer IL-b may be in contact with the side surfaces CNLb-S1 and CNLb-S2 and the top surfaces CNLb-U1 and CNLb-U2 of the second conductive layers CNL-b1 and CNL-b2 to cover the side surfaces of the third layers CL3-1 and CL3-2 and the side and top surfaces of the fourth layers CL4-1 and CL4-2. The second sub-insulating layer IL-b may entirely cover the side surfaces of the third layers CL3-1 and CL3-2 and the side and top surfaces of the fourth layers CL4-1 and CL4-2.

The second sub-insulating layer IL-b may fill a space defined between the second conductive layers CNL-b1 and CNL-b2 to cover the second conductive layers CNL-b1 and CNL-b2. The second sub-insulating layer IL-b may fully fill the space defined between the second conductive layers CNL-b1 and CNL-b2 to entirely cover the side surface of each of the third layers CNL3-1 and CL3-2 and the fourth layer CL4-1 and CL4-2 of the second conductive layers CNL-b1 and CNL-b2 and the top surface of each of the fourth layer CL4-1 and CL4-2.

The second sub-insulating layer IL-b may include a second organic material. The second organic material included in the second sub-insulating layer IL-b may be different from the first organic material included in the first sub-insulating layer IL-a.

The second organic material may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin. For example, the second organic material may include a polyimide-based resin. The second sub-insulating layer IL-b may be made of a second organic material.

The display panel according to one or more embodiments may include first and second conductive layers forming one first connection electrode and may include a first sub-insulating layer arranged between the first conductive layers. The first sub-insulating layer may include a first organic material such as siloxane, polyimide, and/or an acrylic polymer, and a first inorganic material such as silicon dioxide (SiO₂), silicon nitride (Si₃N₄), and/or silicon oxynitride (SiON). Because the first conductive layer and the second conductive layer, each of which includes aluminum, form one first connection electrode, a low-resistance line having a large thickness may be implemented. In some embodiments, a structure in which the first sub-insulating layer fills a stepped portion may be provided between the first conductive layers to easily perform a film formation process and a photo process of the second conductive layer, and thus, as an introduction of an organic flat film between the first conductive layer and the second conductive layer becomes unnecessary, the number of masks desired or required for the process may be reduced, and the process may be simplified to reduce process costs.

FIG. 6B is a cross-sectional view illustrating a portion of the configuration of the display panel according to one or more embodiments of the present disclosure. FIG. 6B illustrates shapes the first insulating layer ISL1 included in the circuit layer DP-CL, a portion of the plurality of first connection electrodes arranged on the first insulating layer ISL1, the second insulating layer ISL2 that covers the first connection electrode, the second connection electrode CNE2 arranged on the second insulating layer ISL2 and electrically connected to the first connection electrode, and the third insulating layer ISL3 that covers the second connection electrode CNE2 in the configurations of the display panel DP illustrated in FIG. 5. In FIG. 6B, the first contact hole defined in the first insulating layer ISL1 may not be provided for convenience of explanation. In describing the first connection electrode CNE1 and the second connection electrode CNE2 according to one or more embodiments with reference to FIG. 6B, the same/similar reference numerals may be used for components that may each independently be the same/similar to those described in FIGS. 1A to 6A, and duplicated descriptions thereof may not be provided.

Referring to FIGS. 5 and 6B together, each of the plurality of pixels may include a connection electrode electrically connected to the transistor. As illustrated in FIG. 6B, each of the plurality of pixels included in the display panel may include a first connection electrode CNE1 and a second connection electrode CNE2. The first and second connection electrodes CNE1 and CNE2 illustrated in FIG. 6B may correspond to the first and second connection electrodes electrically connected to each other in FIG. 5. For example, the first connection electrode CNE1 illustrated in FIG. 6B may correspond to the first-1 connection electrode CNE11 illustrated in FIG. 5, and the second connection electrode CNE2 illustrated in FIG. 6B may correspond to the first connection electrode CNE11 illustrated in FIG. 5.

With respect to the first connection electrode CNE1 illustrated in FIG. 6B, the herein-mentioned contents may be substantially equally applied to the plurality of first connection electrodes CNE1-1 and CNE1-2 in FIG. 6A. For example, the first connection electrode CNE1 may include a first conductive layer CNL-a arranged on the first insulating layer ISL1, and a second conductive layer CNL-b arranged on the first conductive layer CNL-a. The first connection electrode CNE1 may include one electrode in which the first conductive layer CNL-a and the second conductive layer CNL-b are sequentially laminated. The first conductive layer CNL-a may include a first layer CL1 arranged on the first insulating layer ISL1 and a second layer CL2 arranged on the first layer CL1. The second conductive layer CNL-b may include a third layer CL3 arranged on the first conductive layer CNL-a and a fourth layer CL4 arranged on the third layer CL3.

The contents (e.g., amounts) as described herein with respect to the second insulating layer ISL2 in FIG. 6A may be substantially equally applied to the second insulating layer ISL2 illustrated in FIG. 6B. For example, the second insulating layer ISL2 may be arranged on the first insulating layer ISL1 to cover the first connection electrode CNE1. The second insulating layer ISL2 may include a first sub-insulating layer IL-a arranged on the first insulating layer ILS1 and a second sub-insulating layer IL-b arranged on the first sub-insulating layer IL-a. The first sub-insulating layer IL-a may be arranged between adjacent first conductive layers CNL-a. The first sub-insulating layer IL-a may cover at least a portion of the side surface CNLa-S of the first conductive layer CNL-a. The first sub-insulating layer IL-a may not be arranged on the top surface CNLa-U of the first conductive layer CNL-a. The top surface I1-U of the first sub-insulating layer IL-a may be arranged below the top surface CNLa-U of the first conductive layer CNL-a. The first sub-insulating layer IL-a may include a first organic material and a first inorganic material including silicon. The second sub-insulating layer IL-b may be arranged on the first sub-insulating layer IL-a to cover the second conductive layer CNL-b. The second sub-insulating layer IL-b may include a second organic material.

Referring to FIG. 6B, the second connection electrode CNE2 may be arranged on the second insulating layer ISL2. The second connection electrode CNE2 may include a third conductive layer CNL-c and a fourth conductive layer CNL-d, which are sequentially laminated. The third conductive layer CNL-c may include a fifth layer CL5 arranged on the second sub-insulating layer IL-b, and a sixth layer CL6 arranged on the fifth layer CL5. The second connection electrode CNE2 may include one electrode having a structure in which the third conductive layer CNL-c and the fourth conductive layer CNL-d are laminated.

Each of the fifth layer CL5 and the sixth layer CL6 may include a metal material. The fifth layer CL5 and the sixth layer CL6 may include different metal materials. In one or more embodiments, the fifth layer CL5 may include titanium, and the sixth layer CL6 may include aluminum.

The sixth layer CL6 included in the third conductive layer CNL-c may correspond to the uppermost layer of the third conductive layer CNL-c. The sixth layer CL6 may be a layer arranged at the uppermost side of the layers included in the third conductive layer CNL-c. A top surface of the third conductive layer CNL-c may be defined by a top surface of the sixth layer CL6.

The second connection electrode CNE2 may include a fourth conductive layer CNL-d arranged on the third conductive layer CNL-c. The fourth conductive layer CNL-d may be directly arranged on the third conductive layer CNL-c. A bottom surface CNLd-L of the fourth conductive layer CNL-d may be in contact with the third conductive layer CNL-c. The fourth conductive layer CNL-d may include a seventh layer CL7 arranged on the third conductive layer CNL-c and an eighth layer CL8 arranged on the seventh layer CL7. The eighth layer CL8 may be directly arranged on the seventh layer CL7. The seventh layer CL7 may be a layer that is in direct contact with the bottom surface of the eighth layer CL8.

The seventh layer CL7 included in the fourth conductive layer CNL-d may correspond to the lowermost layer in the fourth conductive layer CNL-d. The seventh layer CL7 may be a layer arranged at the lowermost side of the layers included in the fourth conductive layer CNL-d. The bottom surface CNLd-L of the fourth conductive layer CNL-d may be defined by the bottom surface of the seventh layer CL7.

Each of the seventh layer CL7 and the eighth layer CL8 may include a metal material. The seventh layer CL7 and the eighth layer CL8 may include different metal materials. In one or more embodiments, the seventh layer CL7 may include aluminum, and the eighth layer CL8 may include titanium. In one or more embodiments, the sixth layer CL6 included in the third conductive layer CNL-c and the seventh layer CL7 included in the fourth conductive layer CNL-d may include substantially the same material. Each of the sixth layer CL6 and the seventh layer CL7 may include aluminum.

The second connection electrode CNE2 may include one electrode having a four-layer structure in which the fifth layer CL5, the sixth layer CL6, the seventh layer CL7, and the eighth layer CL8 are laminated. In FIG. 6B, a boundary between the sixth layer CL6 and the seventh layer CL7 may be clearly shown as a straight line, but this is shown as an example, and the boundary between the sixth layer CL6 and the seventh layer CL7 may be unclearly shown in a cross-section.

A thickness of the sixth layer CL6 and a thickness of the seventh layer CL7 may be the same. However, one or more embodiments of the present disclosure is not limited thereto. The thickness of the sixth layer CL6 and the thickness of the seventh layer CL7 may be different from each other.

In one or more embodiments, the sum (e.g., total) of the thicknesses of the sixth layer CL6 and the seventh layer CL7 may be at least about 10,000 Å (e.g., or more) and at most about 16,000 Å (e.g., or less). When the sum (e.g., total) of the thicknesses of the sixth layer CL6 and the seventh layer CL7 is less than about 10,000 Å, a desired or suitable resistance reduction effect of the second connection electrode CNE2 may not be expected, and if (e.g., when) the sum (e.g., total) of the thickness of the sixth layer CL6 and the thickness of the seventh layer CL7 exceeds about 16,000 Å, the thickness of the second connection electrode CNE2 may become excessively (or substantially) thick, making it difficult to miniaturize the display device. As the sum (e.g., total) of the thickness of the sixth layer CL6 and the thickness of the seventh layer CL7 satisfies the herein-mentioned range, resistance of the electrode may be effectively reduced, and an occurrence of electrode defects in the process may be reduced to improve process reliability. Conductivity of each of the sixth layer CL6 and the seventh layer CL7 may substantially determine conductivity of the second connection electrode CNE2. As the sum (e.g., total) of the thicknesses of the sixth layer CL6 and the seventh layer CL7 increases, the second connection electrode CNE2 having low resistance characteristics may be formed. Thus, the display panel DP (FIG. 1B) may be driven at a high speed, the display characteristics of the display panel DP (FIG. 1B) may be improved, and power consumption may be reduced.

The third insulating layer ISL3 may be arranged on the second insulating layer ISL2 to cover the second connection electrode CNE2. The third insulating layer ISL3 may include a third sub-insulating layer IL-c arranged on the second sub-insulating layer IL-b and a fourth sub-insulating layer IL-d arranged on the third sub-insulating layer IL-c.

The third sub-insulating layer IL-c may be in contact with the third conductive layer CNL-c. The third sub-insulating layer IL-c may cover a portion of the side surface CNLc-S of the third conductive layer CNL-c. The third sub-insulating layer IL-c may be in contact with each of the fifth layer CL5 and the sixth layer CL6 of the third conductive layer CNL-c. The third sub-insulating layer IL-c may entirely cover a side surface of the fifth layer CL5 to partially cover the side surface of the sixth layer CL6.

The third sub-insulating layer IL-c may not be arranged on the top surface CNLc-U of the third conductive layer CNL-c. The third sub-insulating layer IL-c may be arranged to be in contact with only the side surface CNLc-S of the third conductive layer CNL-c and may not be in contact with the top surface CNLc-U of the third conductive layer CNL-c. The third sub-insulating layer IL-c may not be arranged on the top surface CNLc-U of the third conductive layer CNL-c, but may expose the top surface CNLc-U of the third conductive layer CNL-c. Thus, the fourth conductive layer CNL-d may be directly arranged on the top surface CNLc-U of the third conductive layer CNL-c.

The top surface I2-U of the third sub-insulating layer IL-c may be arranged below the top surface CNLc-U of the third conductive layer CNL-c. For example, the top surface I2-U of the third sub-insulating layer IL-c may be defined to be further adjacent to the second insulating layer ISL2 than the top surface CNLc-U of the third conductive layer CNL-c. However, one or more embodiments of the present disclosure is not limited thereto. The top surface I2-U of the third sub-insulating layer IL-c may be parallel to the top surface CNLc-U of the third conductive layer CNL-c. For example, the top surface I2-U of the third sub-insulating layer IL-c may define one surface aligned with the top surface CNLc-U of the third conductive layer CNL-c.

Although FIG. 6B illustrates an example in which the top surface I2-U of the third sub-insulating layer IL-c has a flat shape, one or more embodiments of the present disclosure is not limited thereto. The top surface I2-U of the third sub-insulating layer IL-c may have a curved shape. For example, the top surface I2-U of the third sub-insulating layer IL-c may have a curved shape that is recessed to be adjacent to the second insulating layer ISL2.

The third sub-insulating layer IL-c may be arranged on the same layer as the third conductive layer CNL-c. The third sub-insulating layer IL-c and the third conductive layer CNL-c may be arranged on the second sub-insulating layer IL-b. The third sub-insulating layer IL-c may cover a portion of the top surface of the second sub-insulating layer IL-b that is exposed because the third conductive layer CNL-c is not arranged.

At least a portion of the bottom surface of the fourth conductive layer CNL-d may be in contact with the third sub-insulating layer IL-c. A bottom surface CNLd-L of the fourth conductive layer CNL-d corresponding to an edge of the fourth conductive layer CNL-d may be in contact with the third sub-insulating layer IL-c.

A side surface CNLc-S of the third conductive layer CNL-c may be misaligned with a side surface CNLd-S of the fourth conductive layer CNL-d. For example, a top surface CNLc-U of the third conductive layer CNL-c may be misaligned with the bottom surface CNLd-L of the fourth conductive layer CNL-d.

At least a portion of the top surface CNLc-U of the third conductive layer CNL-c may be in contact with the fourth conductive layer CNL-d. A planar area of the top surface CNLc-U of the third conductive layer CNL-c may be less than that of the bottom surface CNLd-L of the fourth conductive layer CNL-d. A planar area of the bottom surface CNLd-L of the fourth conductive layer CNL-d may be greater than that of the top surface CNLc-U of the third conductive layer CNL-c, and the top surface CNLc-U of the third conductive layer CNL-c may be fully covered by the fourth conductive layer CNL-d. However, one or more embodiments of the present disclosure is not limited thereto.

The fourth sub-insulating layer IL-d may be arranged on the third sub-insulating layer IL-c and cover the fourth conductive layer CNL-d. The fourth sub-insulating layer IL-d may cover the fourth conductive layer CNL-d and may be in contact with the third conductive layer CNL-c. The fourth sub-insulating layer IL-d may cover the side surface CNLd-S and the top surface CNLd-U of the fourth conductive layer CNL-d. The fourth sub-insulating layer IL-d may cover the side surface of the seventh layer CL7 and the side and top surfaces of the eighth layer CL8 of the fourth conductive layer CNL-d. The fourth sub-insulating layer IL-d may entirely cover the seventh layer CL7 and the side and top surfaces of the eighth layer CL8.

In one or more embodiments, each of the plurality of pixels included in the display panel DP may include a second connection electrode CNE2. Each of the second connection electrodes included in the plurality of pixels may have substantially the same structure as the structure of the second connection electrode CNE2 illustrated in FIG. 6B. For example, each of the second connection electrodes may include a third conductive layer CNL-c and a fourth conductive layer CNL-d, which are sequentially laminated.

The third sub-insulating layer IL-c may be arranged between the adjacent third conductive layers CNL-c. The third sub-insulating layer IL-c may be arranged between the third conductive layers CNL-c to fill a space between the third conductive layers CNL-c. The third sub-insulating layer IL-c may fill the space defined between the third conductive layers CNL-c. The third sub-insulating layer IL-c may fill a portion of the space defined between the third conductive layers CNL-c. The third sub-insulating layer IL-c may cover a portion of the entire side surface of the fifth layer CL5 and a portion of the side surface of the sixth layer CL6 to fill a space defined between the third conductive layers CNL-c. However, one or more embodiments of the present disclosure is not limited thereto, and the third sub-insulating layer IL-c may fully fill the space defined between the third conductive layers CNL-c. For example, the third sub-insulating layer IL-c may entirely cover the side surface of each of the fifth layer CL5 and the sixth layer CL6 of the third conductive layers CNL-c and may fully fill the space between the third conductive layers CNL-c so that the top surface I2-U of the third sub-insulating layer IL-c is parallel to the top surface CNLc-U of the third conductive layers CNL-c.

The fourth sub-insulating layer IL-d may fill the space defined between the fourth conductive layers CNL-d to cover the fourth conductive layer CNL-d. The fourth sub-insulating layer IL-d may fully fill the space defined between the fourth conductive layers CNL-d to entirely cover the side surface CNLd-S and the top surface CNLd-U of each of the fourth conductive layers CNL-d.

The third sub-insulating layer IL-c may include a first organic material and a first inorganic material. The first inorganic material included in the third sub-insulating layer IL-c may be an inorganic material including silicon. The first inorganic material included in the third sub-insulating layer IL-c may include at least one of silicon dioxide (SiO₂), silicon nitride (Si₃N₄), or silicon oxynitride (SiON). For example, the first inorganic material may be silicon dioxide (SiO₂). The first organic material included in the third sub-insulating layer IL-c may include at least one of siloxane, polyimide, or an acrylic polymer. The first organic material may be, for example, siloxane. The third sub-insulating layer IL-c may be made of a first inorganic material and a first organic material.

With respect to the first organic material and the first inorganic material included in the third sub-insulating layer IL-c, a content (e.g., amount) of the first inorganic material may be greater than that of the first organic material compared to the total content (e.g., amount) of the third sub-insulating layer IL-c. The content (e.g., amount) of the first organic material compared to the total content (e.g., amount) of the third sub-insulating layer IL-c may be about 10 wt % or more and less than about 50 wt %. When the content (e.g., amount) of the first organic material in the third sub-insulating layer IL-c is less than about 10 wt %, a coating property of the filling material may decrease in the process of forming the third sub-insulating layer IL-c, and thus, the third sub-insulating layer IL-c may not be arranged only between the third conductive layers CNL-c, but be arranged on the top surface CNLc-U of each of the third conductive layers CNL-c. When the content (e.g., amount) of the first organic material in the third sub-insulating layer IL-c is about 50 wt % or more, the third sub-insulating layer IL-c may not be patterned to be arranged only between the third conductive layers CNL-c.

The fourth sub-insulating layer IL-d may include a second organic material. The second organic material included in the fourth sub-insulating layer IL-d may be different from the first organic material included in the third sub-insulating layer IL-c. The second organic material may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin. For example, the second organic material may include a polyimide-based resin. The fourth sub-insulating layer IL-d may be made of a second organic material.

In one or more embodiments, the display device DD may be a component of and/or applied to electronic devices such as smartphones, televisions, monitors, tablets, electric vehicles, mobile phones, tablet personal computers (PC), mobile communication terminals, electronic notebooks, electronic books, portable multimedia players (PMP), navigation devices, ultra-mobile personal computers (UMPC), laptop computers, billboards, Internet of Things (IOT) devices, smartwatches, watch phones, or head-mounted displays (HMD). For example, the display device DD may be applied to a display unit of a television, a laptop computer, a monitor, a billboard, or the Internet of Things (IOT). Alternatively, in one or more embodiments, the display device DD may be applied to a smartwatch, a watch phone, and/or a head-mounted display device (HMD) for implementing virtual reality and/or augmented reality.

Hereinafter, a method for manufacturing a display panel according to one or more embodiments will be described with reference to the drawings. In the description of the method for manufacturing the display panel according to one or more embodiments, description of contents duplicated with the contents of the display panel of the herein-described embodiment will not be provided.

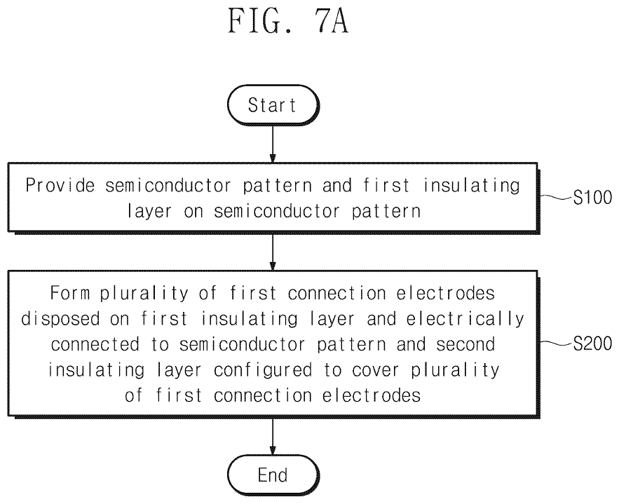

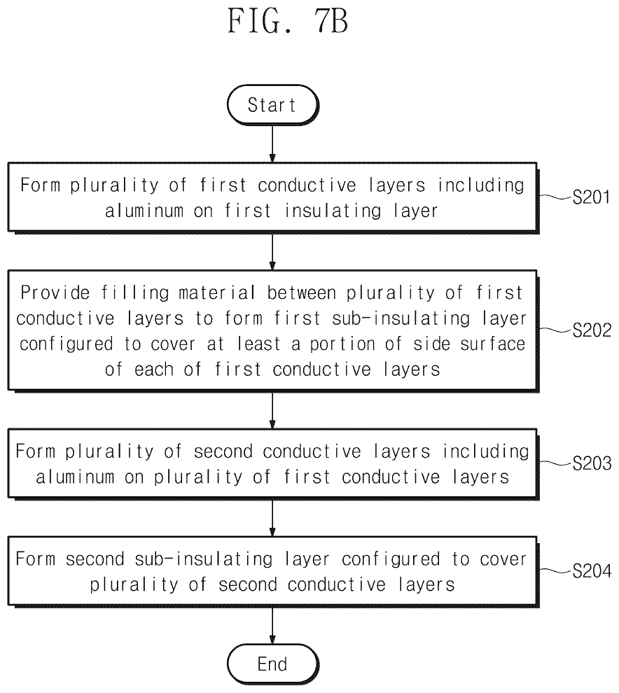

FIG. 7A is a flowchart illustrating a method for manufacturing a display panel according to one or more embodiments of the present disclosure. FIG. 7B is a flowchart detailing steps of forming a plurality of first connection electrodes and a second insulating layer according to one or more embodiments of the present disclosure.

Referring to FIG. 7A, a method for manufacturing a display panel according to one or more embodiments of the present disclosure may include a step (e.g., act or task) (S100) of providing a semiconductor pattern and a first insulating layer arranged on the semiconductor pattern and a step (e.g., act or task) (S200) of forming a plurality of first connection electrodes arranged on the first insulating layer and electrically connected to the semiconductor pattern and a second insulating layer that covers the plurality of first connection electrodes.

Referring to FIG. 7B, in the method for manufacturing the display panel according to one or more embodiments, the step (e.g., act or task) (S200) of forming the plurality of first connection electrodes and the second insulating layer may include a step (e.g., act or task) (S210) of forming a plurality of first conductive layers including aluminum on the first insulating layer ISL1, a step (e.g., act or task) (S202) of providing a filling material between the plurality of first conductive layers to form a first sub-insulating layer covering at least a portion of a side surface of each of the first conductive layers, a step (e.g., act or task) (S203) of forming a plurality of second conductive layers including aluminum on the plurality of first conductive layers, and a step (e.g., act or task) (S204) of forming a second sub-insulating layer covering the plurality of second conductive layers.

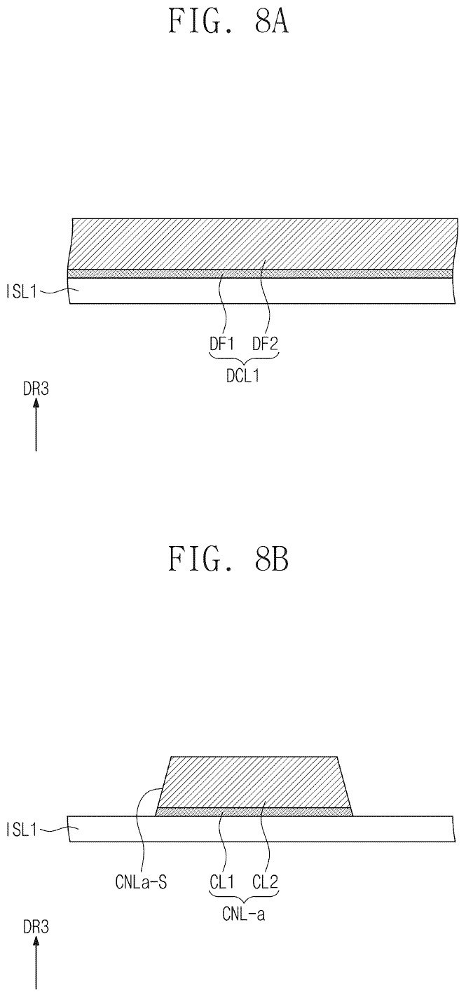

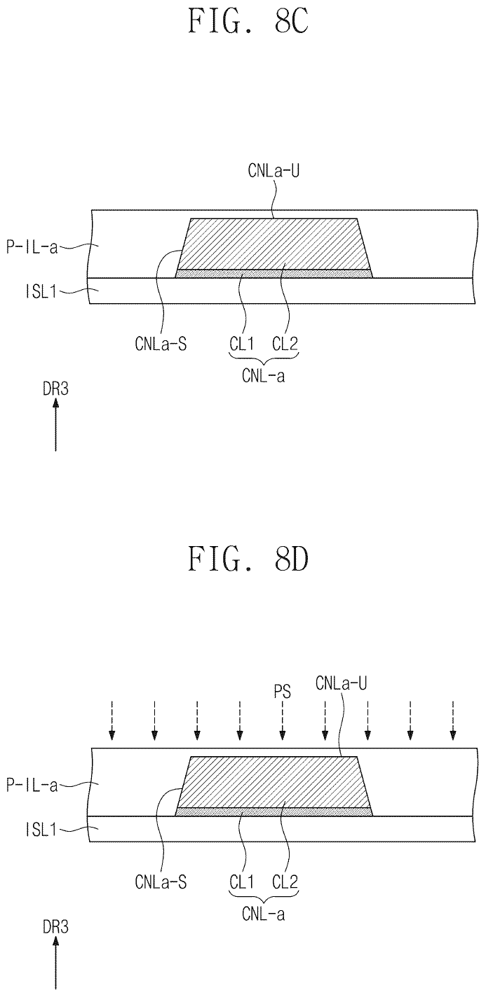

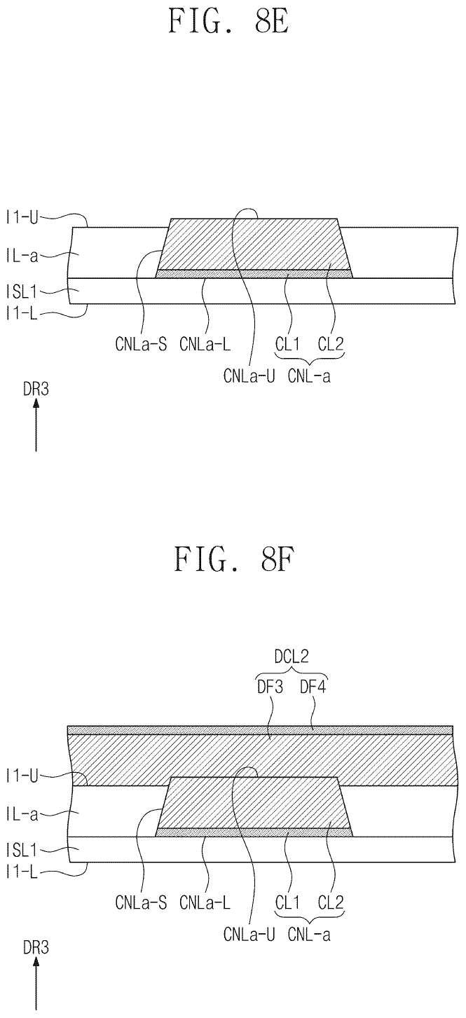

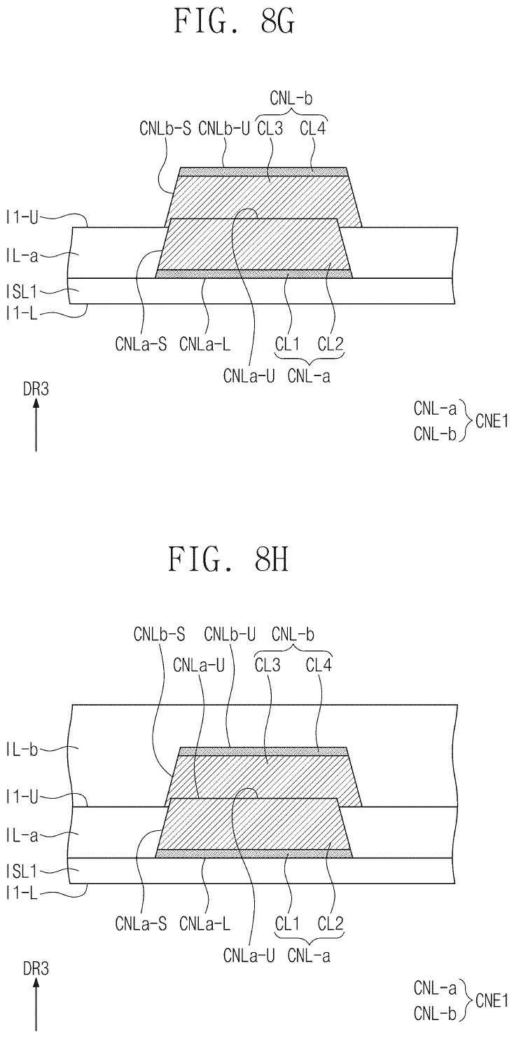

FIGS. 8A to 8H are cross-sectional views illustrating some steps (e.g., acts or tasks) of the method for manufacturing the display panel according to one or more embodiments of the present disclosure. FIGS. 8A to 8H illustrate states in some steps (e.g., acts or tasks) of the method for manufacturing the display panel in the cross-section corresponding to FIG. 6B, respectively. For convenience of explanation, FIGS. 8A to 8H may illustrate a step (e.g., act or task) of forming one first connection electrode CNE1 on the first insulating layer ISL1. All of the plurality of first connection electrodes CNE1 formed on the first insulating layer ISL1 may be formed through substantially the same process as the process described in more detail later.

Referring to FIG. 8A, the method for manufacturing the display panel according to one or more embodiments of the present disclosure may include a step (e.g., act or task) of providing a preliminary display panel including semiconductor patterns SP1 and SP2 (see FIG. 5) and the first insulating layer ISL1 arranged on the semiconductor patterns SP1 and SP2 (see FIG. 5). In some embodiments, a first contact hole exposing a portion of the semiconductor patterns SP1 and SP2 (see FIG. 5) may be defined in the first insulating layer ISL1 in the preliminary display panel. The first conductive layers CNL-a, which are described in more detail elsewhere herein, may be formed to correspond to the first contact hole and may be electrically connected to the semiconductor patterns SP1 and SP2 (see FIG. 5) through the first contact hole.

Referring to FIGS. 8A and 8B, the method for manufacturing the display panel according to one or more embodiments of the present disclosure may include a step (e.g., act or task) of forming a plurality of first conductive layers CNL-a on the first insulating layer ISL1. The step (e.g., act or task) of forming the plurality of first conductive layers CNL-a may include a step (e.g., act or task) of forming a preliminary first conductive layer DCL1 on the first insulating layer ISL1, and a step (e.g., act or task) of patterning the preliminary first conductive layer DCL1. The step (e.g., act or task) of forming the preliminary first conductive layer DCL1 may include a step (e.g., act or task) of forming a first conductive film DF1 on the first insulating layer ISL1 and a step (e.g., act or task) of forming a second conductive film DF2 on the first conductive film DF1. In this specification, the first conductive film DF1 may be referred to as a preliminary first layer, and the second conductive film DF2 may be referred to as a preliminary second layer.

Each of the first conductive film DF1 and the second conductive film DF2 may include a metal material. The first conductive film DF1 and the second conductive film DF2 may include different metal materials. In one or more embodiments, the first conductive film DF1 may include titanium, and the second conductive film DF2 may include aluminum. Thus, each of the first conductive layers CNL-a may have a structure in which titanium (Ti)/aluminum (Al) are laminated.

After the step (e.g., act or task) of forming the preliminary first conductive layer DCL1 on the first insulating layer ISL1, a step (e.g., act or task) of patterning the first conductive film DF1 and the second conductive film DF2 may be performed. The step (e.g., act or task) of patterning the first conductive film DF1 and the second conductive film DF2 may be a step (e.g., act or task) of dry etching or wet etching the first conductive film DF1 and the second conductive film DF2. For example, the first conductive film DF1 and the second conductive film DF2 may be dry etched.

In the step (e.g., act or task) of patterning the first conductive film DF1 and the second conductive film DF2, after patterning a first photoresist pattern on the second conductive film DF2, the first and second conductive films DF1 and DF2 may be etched to form a plurality of first conductive layers CNL-a including the first and second layers CL1 and CL2. Thereafter, the first photoresist pattern may be removed from the first conductive layers CNL-a to expose a top surface of each of the first conductive layers CNL-a. In some embodiments, in the step (e.g., act or task) of patterning the first and second conductive films DF1 and DF2, a portion of the top surface of the first insulating layer ISL1 may be exposed.

Each of the plurality of first conductive layers CNL-a may include a first layer CL1 and a second layer CL2 formed by patterning the first conductive film DF1 and the second conductive film DF2. Each of the plurality of first conductive layers CNL-a may include a first layer CL1 and a second layer CL2, which are sequentially laminated.

Referring to FIGS. 6A and 8C to 8E, the method for manufacturing the display panel according to one or more embodiments of the present disclosure may provide the filling material between the plurality of first conductive layers CNL-a, and thus, the first conductive layers CNL-a may include a step (e.g., act or task) of forming a first sub-insulating layer IL-a covering at least a portion of each side surface. The first sub-insulating layer IL-a may be formed between the first conductive layers CNL-a. The first sub-insulating layer IL-a may be arranged between the first conductive layers CNL-a to cover at least a portion of the side surface CNLa-S of each of the first conductive layers CNL-a.

In one or more embodiments, the filling material for forming the first sub-insulating layer IL-a may not be patterned and provided only between the first conductive layers CNL-a, but may be commonly provided on both (e.g., simultaneously) an upper portion of each of the first conductive layers CNL-a and between the first conductive layers CNL-a. As the filling material has flowability, the filling material provided on the upper portion of each of the first conductive layers CNL-a may move between the first conductive layers CNL-a and then be cured to form the first sub-insulating layer IL-a.

The filling material may include a first organic material and a second organic material. The first inorganic material included in the filling material may be an inorganic material including silicon. The first inorganic material included in the filling material may include at least one of silicon dioxide (SiO₂), silicon nitride (Si₃N₄), or silicon oxynitride (SiON). For example, the first inorganic material may be silicon dioxide (SiO₂). The first organic material included in the filling material may include at least one of siloxane, polyimide, or an acrylic polymer. The first organic material may be, for example, siloxane. The first sub-insulating layer IL-a may be made of a first inorganic material and a first organic material.

With respect to the first organic material and the first inorganic material contained in the filling material, the content (e.g., amount) of the first inorganic material may be greater than the content (e.g., amount) of the first organic material compared to the combined content (e.g., amount) of the first organic material and the second organic material included in the filling material. The content (e.g., amount) of the first organic material compared to the combined content (e.g., amount) of the first organic material and the second organic material included in the filling material may be about 10 wt % or more and less than about 50 wt %.

A weight ratio of solid contents included in the filling material may be at most about 2 wt % (e.g., or less). In addition to the first organic material and the first inorganic material described herein, the filling material may further include a solvent.

With respect to the entire filling material, the sum of the solid contents of the first organic material and the first inorganic material may be at most about 2 wt % (e.g., or less). When the weight ratio of the solid content (e.g., amount) included in the filling material exceeds about 2 wt %, the flowability of the filling material may be reduced, and the filling material provided on the upper portion of each of the first conductive layers CNL-a may not move between the first conductive layers CNL-a, but may remain.

The filling material may be made of the first organic material, the first inorganic material, and the solvent. The filling material may be a material that does not include or contain any other materials other than the first organic material, the first inorganic material, and the solvent. In one or more embodiments, the filling material may not include (e.g., may exclude) a photosensitizer. In the process of curing the filling material to form the first sub-insulating layer IL-a, because the filling material does not include the photosensizer, a separate exposure process may not be provided. The filling material may be naturally cured or thermally cured to form the first sub-insulating layer IL-a.

Referring to FIGS. 8C and 8D, in the step (e.g., act or task) of providing the filling material between the first conductive layers CNL-a, a first preliminary sub-insulating layer P-IL-a may be formed on the first insulating layer ISL1. The first preliminary sub-insulating layer P-IL-a may entirely cover a side surface CNLa-S of the first conductive layers CNL-a, and a top surface CNL-a of the first conductive layers CNL-a to cover at least portion of the top surface CNLa-U of the first conductive layers CNL-a. As illustrated in FIG. 8C, if (e.g., when) the filling material is provided on the upper portion of the first conductive layers CNL-a, a portion of the filling material may not move between the first conductive layers CNL-a, but may remain on the top surface CNLa-U of each of the first conductive layers CNL-a and then be cured. Thus, the first preliminary sub-insulating layer P-IL-a may be arranged on at least a portion of the top surface CNLa-U of each of the first conductive layers CNL-a. As illustrated in FIG. 8C, the first preliminary sub-insulating layer P-IL-a may fully (e.g., entirely) cover the top surface CNLa-U of each of the first conductive layers CNL-a. However, one or more embodiments of the present disclosure is not limited thereto, and the first preliminary sub-insulating layer P-IL-a may be formed in one or more suitable pattern shapes on the top surface CNLa-U of each of the first conductive layers CNL-a.

The method for manufacturing the display panel according to one or more embodiments of the present disclosure may further include a step (e.g., act or task) of ashing the top surface CNLa-U of each of the first conductive layers CNL-a after the step (e.g., act or task) of providing the filling material between the first conductive layers CNL-a. In the step (e.g., act or task) of ashing the top surface CNLa-U of each of the first conductive layers CNL-a, a portion of the first conductive layers CNL-a and the first preliminary sub-insulating layer P-IL-a may be removed. In the ashing process, the first preliminary sub-insulating layer P-IL-a formed on the top surface CNLa-U of each of the first conductive layers CNL-a may be removed through plasma PS to expose the top surface CNLa-U of each of the first conductive layers CNL-a.

The first preliminary sub-insulating layer P-IL-a formed on the top surface CNLa-U of each of the first conductive layers CNL-a may be removed to form a first sub-insulating layer IL-a that is arranged to be in contact with only the side surface CNLa-S of each of the first conductive layer CNL-a. The first sub-insulating layer IL-a may be formed to be in contact with only the side surface CNLa-S of each of the first conductive layers CNL-a and may not be in contact with the top surface CNLa-U. The first sub-insulating layer IL-a may be formed so as not to be arranged on the top surface CNLa-U of the first conductive layers CNL-a. However, one or more embodiments of the present disclosure is not limited thereto, and the filling material for forming the first sub-insulating layer IL-a may be patterned and provided only between the first conductive layers CNL-a so as not to be arranged on the top surface CNLa-U of each of the first conductive layers CNL-a. In this case, the step (e.g., act or task) of ashing the first conductive layers CNL-a may not be provided.

Referring to FIG. 8E, the top surface I1-U of the first sub-insulating layer IL-a may be arranged below the top surface CNLa-U of each of the first conductive layers CNL-a. The top surface I1-U of the first sub-insulating layer IL-a may be defined to be further (e.g., more) adjacent to the first insulating layer ISL1 than the top surface CNLa-U of each of the first conductive layers CNL-a. In the step (e.g., act or task) of ashing the top surface CNLa-U of each of the first conductive layers CNL-a, an etch rate of the first conductive layers CNL-a and an etch rate of the first preliminary sub-insulating layer P-IL-a may be different from each other. The first conductive layers CNL-a may be etched at a first etch rate, and the first preliminary sub-insulating layer P-IL-a may be etched at a second etch rate that is different from the first etch rate. The second etch rate may be greater than the first etch rate. Thus, in the step (e.g., act or task) of ashing (removing or etching) the first conductive layers CNL-a, the top surface of the first preliminary sub-insulating layer P-IL-a will be etched (removed) more than the top surface of the first conductive layers CNL-a. The top surface of the first sub-insulating layer IL-a formed later may be formed to be arranged below the top surface of the first conductive layers CNL-a. For example, the top surface of the first preliminary sub-insulating layer P-IL-a is etched more than the top surface of the first conductive layers CNL-a. The top surface of the subsequently formed first sub-insulating layer IL-a is thus arranged below the top surface of the first conductive layers CNL-a. In this specification, the “etch rate” may refer to an amount of etching in a film thickness direction per second. The “etch rate” may refer to an etch rate at room temperature (about 25° C.). A unit of the etch rate may be expressed as angstrom per second (Å/s).

Referring to FIGS. 8F and 8G, the method for manufacturing the display panel according to one or more embodiments of the present disclosure may include a step (e.g., act or task) of forming a plurality of second conductive layers CNL-b including aluminum on the plurality of first conductive layers CNL-a. The step (e.g., act or task) of forming the plurality of second conductive layers CNL-b may include a step (e.g., act or task) of forming a preliminary second conductive layer DCL2 on the plurality of first conductive layers CNL-a and the first sub-insulating layer IL-a and a step (e.g., act or task) of patterning the preliminary second conductive layer DCL2. The step (e.g., act or task) of forming the preliminary second conductive layer DCL2 may include a step (e.g., act or task) of forming a third conductive film DF3 on the plurality of first conductive layers CNL-a and the first sub-insulating layer IL-a and a step (e.g., act or task) of forming a fourth conductive film DF4 on the third conductive film DF3. In this specification, the third conductive film DF3 may be referred to as a preliminary third layer, and the fourth conductive film DF4 may be referred to as a preliminary fourth layer.

Each of the third conductive film DF3 and the fourth conductive film DF4 may include a metal material. The third conductive film DF3 and the fourth conductive film DF4 may include different metal materials. In one or more embodiments, the third conductive film DF3 may include aluminum, and the fourth conductive film DF4 may include titanium. Thus, the second conductive layers CNL-b may have a structure in which aluminum (Al)/titanium (Ti) are laminated.

After forming the preliminary second conductive layer DCL2 on the first conductive layers CNL-a and the first sub-insulating layer IL-a, a step (e.g., act or task) of patterning the third conductive film DF3 and the fourth conductive film DF4 may be performed. The step (e.g., act or task) of patterning the third and fourth conductive films DF3 and DF4 may be a step (e.g., act or task) of dry etching or wet etching the third and fourth conductive films DF3 and DF4. For example, the third and fourth conductive films DF3 and DF4 may be dry etched.

In the step (e.g., act or task) of patterning the third and fourth conductive films DF3 and DF4, after patterning a second photoresist pattern on the fourth conductive film DF4, the third and fourth conductive films DF3 and DF4 may be etched to form a plurality of second conductive layers CNL-b including the third and fourth layers CL3 and CL4. Thereafter, the second photoresist pattern may be removed from the second conductive layers CNL-b to expose the top surface of each of the second conductive layers CNL-b. In some embodiments, in the step (e.g., act or task) of patterning the third and fourth conductive films DF3 and DF4, a portion of the top surface of the first sub-insulating layer IL-a may be exposed.

Each of the second conductive layers CNL-b may include a third layer CL3 and a fourth layer CL4, which are formed by patterning the third conductive film DF3 and the fourth conductive film DF4. Each of the second conductive layers CNL-b may include a third layer CL3 and a fourth layer CL4, which are sequentially laminated. The third layer CL3 may be formed to be in contact with the top surface of the second layer CL2.

Referring to FIG. 8H, the method for manufacturing the display panel according to one or more embodiments of the present disclosure may include a step (e.g., act or task) of forming a second sub-insulating layer IL-b that covers the plurality of second conductive layers CNL-b. A material forming the second sub-insulating layer IL-b may be provided on the plurality of second conductive layers CNL-b to form the second sub-insulating layer IL-b that covers the second conductive layers CNL-b. The second sub-insulating layer IL-b may cover both (e.g., simultaneously) the side surface CNLb-S of each of the second conductive layers CNL-b and the top surface CNLb-U of each of the second conductive layers CNL-b. The material for forming the second sub-insulating layer IL-b may not be patterned and provided only between the second conductive layers CNL-b, but may be commonly provided on both (e.g., simultaneously) the top of each of the second conductive layers CNL-b and between the second conductive layer CNL-b.

The material forming the second sub-insulating layer IL-b may include a second organic material. The second organic material may be different from the first organic material included in the first sub-insulating layer IL-a. The second organic material may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin. For example, the second organic material may include a polyimide-based resin.

The material forming the second sub-insulating layer IL-b may include a second organic material and a solvent. In some embodiments, the material forming the second sub-insulating layer IL-b may further include a photosensitizer in addition to the second organic material and the solvent. Because the material forming the second sub-insulating layer IL-b includes the photosensitizer, an exposure process may be provided in the step (e.g., act or task) of forming a contact hole in the second sub-insulating layer IL-b.

In one or more embodiments, after the step (e.g., act or task) of forming the second sub-insulating layer IL-b, a step (e.g., act or task) of forming a second contact hole that exposes at least a portion of the plurality of first connection electrodes CNE1 to the second sub-insulating layer IL-b may be performed. After forming a third photoresist pattern on the second sub-insulating layer IL-b, the second sub-insulating layer IL-b may be etched using the third photoresist pattern as a mask to form the second contact hole. Thereafter, the third photoresist pattern may be removed after the step (e.g., act or task) of forming the second contact hole. The first connection electrode and the first electrode AE (see FIG. 5) of the light emitting element may be electrically connected to each other through the second contact hole. In one or more embodiments, the first connection electrode and the second connection electrode CNE2 (see FIG. 5) may be electrically connected to each other through the second contact hole.

In one or more embodiments, the method for manufacturing the display panel may further includes a step (e.g., act or task) of forming a second connection electrode CNE2 electrically connected to at least a portion of the plurality of first connection electrodes CNE1 and a step (e.g., act or task) of forming a third insulating layer ISL3 that covers the second connection electrode CNE2. After forming the second contact hole exposing at least a portion of the plurality of first connection electrodes in the second sub-insulating layer IL-b, the second connection electrode CNE2 may be formed on the second sub-insulating layer IL-b. The process of forming the second connection electrode CNE2 may be substantially the same as the process of forming the first connection electrode CNE1 described with reference to FIGS. 8A to 8H. As a result, the display panel DP including the plurality of first connection electrodes CNE11, CNE12, and CNE13 illustrated in FIG. 5, the second insulating layer ISL2 covering the plurality of first connection electrodes CNE11, CNE12, and CNE13 and arranged on the first insulating layer ISL1, the second connection electrode CNE2 electrically connected to at least a portion of the plurality of first connection electrodes CNE11, CNE12, and CNE13, and the third insulating layer ISL3 that cover the second connection electrode CNE2 and is arranged on the second insulating layer ISL2 may be formed.

Aluminum may have excellent or suitable etching processability and may be applied to the connection electrode of the display panel. However, to implement a high-resolution display panel, low-resistance characteristics of lines may be continuously desired or required. To implement this characteristics, a thickness of the line may increase, or the conductive layers may be connected to each other through the contact hole in the structure including the plurality of conductive layers including aluminum and the organic flat layer arranged between the conductive layers, thereby implementing one electrode. However, if (e.g., when) increasing in thickness of the aluminum metal film, an etch delay may occur above a certain thickness, and if (e.g., when) sputtering a thick film, a substrate may be heated by plasma heat, which may cause substrate bending, and thus, there may be a limitation in increasing in thickness of the aluminum metal film. Thus, a method of electrically connecting the plurality of conductive layers by introducing an organic flat layer without increasing in thickness of the aluminum film may be considered. However, in this case, the mask process for forming the contact hole may be involved to increase in manufacturing time and manufacturing cost and also increase in occurrence of defects, thereby deteriorating the process efficiency.

According to one or more embodiments of the present disclosure, the first and second conductive layers including (e.g., constituting) one first connection electrode may be formed through different processes. As the first and second conductive layers are formed through the separate processes, the limitation that the substrate is bent due to the plasma heat during the sputtering may be prevented or reduced. In some embodiments, because the first conductive layer and the second conductive layer, each of which includes aluminum, form one first connection electrode, the low-resistance line having the large thickness may be implemented. In some embodiments, according to one or more embodiments of the present disclosure, a step (e.g., act or task) of forming the first sub-insulating layer arranged between the first conductive layers may be performed between the first conductive layer formation process and the second conductive layer formation process. The first sub-insulating layer may include a first organic material such as siloxane, polyimide, and/or an acrylic polymer, and a first inorganic material such as silicon dioxide (SiO₂), silicon nitride (Si₃N₄), and/or silicon oxynitride (SiON). Therefore, the structure in which the first sub-insulating layer fills a stepped portion may be provided between the first conductive layers to easily perform the film formation process and the photo process of the second conductive layer, and thus, as the introduction of the organic flat film between the first conductive layer and the second conductive layer becomes unnecessary, the number of masks desired or required for the process may be reduced, and the process may be simplified to reduce process costs.

In the display panel according to one or more embodiments of the present disclosure, the resistance of the connection electrode may be reduced to improve the display characteristics of the display panel and providing the high-resolution display panel.

In the method for manufacturing the display panel according to one or more embodiments of the present disclosure, the number of mask processes desired or required during the process may be reduced to improve the process efficiency and the process reliability.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6.Applicant therefore reserves the right to amend this specification, including the claims, to expressly recite any sub-range subsumed within the ranges expressly recited herein.

The display panel, the display device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display panel and/or the display device may be formed on one integrated circuit (IC) chip or on separate IC chips. Further, the one or more suitable components of the display panel and/or the display device may be implemented on a flexible printed circuit film, a tape carrier package (TCP), a printed circuit board (PCB), or formed on one substrate. Further, the one or more suitable components of the display panel and/or the display device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

It will be apparent to those skilled in the art that one or more suitable modifications and variations can be made in the present disclosure. Thus, it is intended that the present disclosure covers the modifications and variations of this invention provided they come within the scope of the appended claims and their equivalents. Hence, the real protective scope of the present disclosure shall be determined by the technical scope of the accompanying claims, and equivalents thereof.

1 what is claimed is:

1. A display panel comprising:
a circuit layer; and
a light emitting element on the circuit layer,
wherein the circuit layer comprises:
a semiconductor pattern;
a first insulating layer comprising a first contact hole configured to expose a portion of the semiconductor pattern;
a plurality of first connection electrodes on the first insulating layer and electrically connected to the semiconductor pattern through the first contact hole; and
a second insulating layer configured to cover the plurality of first connection electrodes and on the first insulating layer,
wherein each of the plurality of first connection electrodes comprises:
a first conductive layer comprising aluminum; and
a second conductive layer on the first conductive layer and comprising aluminum,
wherein the second insulating layer comprises:
a first sub-insulating layer between a pair of adjacent first conductive layers; and
a second sub-insulating layer on the first sub-insulating layer configured to cover the second conductive layer, and
wherein the first sub-insulating layer comprises:
a first inorganic material comprising silicon; and
a first organic material.

2. The display panel of claim 1, wherein,
the first organic material comprises at least one of siloxane, polyimide, or an acrylic polymer, and
the first inorganic material comprises at least one of silicon dioxide (SiO₂), silicon nitride (Si₃N₄), or silicon oxynitride (SiON).

3. The display panel of claim 1, wherein the second sub-insulating layer comprises a second organic material different from the first organic material.

4. The display panel of claim 1, wherein the first sub-insulating layer is on a side surface of each of the first conductive layers and comprises a bottom surface that is aligned with a bottom surface of each first conductive layer.

5. The display panel of claim 1, wherein a top surface of the first sub-insulating layer is below a top surface of each of the first conductive layers.

6. The display panel of claim 1, wherein at least a portion of a bottom surface of each of the second conductive layers is on the first sub-insulating layer.

7. The display panel of claim 1, wherein at least a portion of a top surface of the first conductive layer is on the second conductive layer, and
a planar area of the top surface of the first conductive layer is less than a planar area of a bottom surface of the second conductive layer.

8. The display panel of claim 1, wherein, in a cross-sectional view, a side surface of the first conductive layer and a side surface of the second conductive layer are misaligned.

9. The display panel of claim 1, wherein the second sub-insulating layer is on a side surface and a top surface of each second conductive layer.

10. The display panel of claim 1, wherein the light emitting element comprises a pixel electrode electrically connected to the plurality of first connection electrodes.

11. The display panel of claim 1, wherein
the first conductive layer comprises a first layer on the first insulating layer and comprising titanium and a second layer on the first layer and comprising aluminum, and
the second conductive layer comprises a third layer on the second layer and comprising aluminum, and a fourth layer on the third layer and comprising titanium.

12. The display panel of claim 11, wherein the third layer is directly on the second layer, and a sum of a thickness of the second layer and a thickness of the third layer is at least about 10,000 angstrom (Å) and at most about 16,000 Å.

13. The display panel of claim 1, wherein a second contact hole through which the plurality of first connection electrodes is exposed is defined in the second insulating layer,
wherein the circuit layer comprises:
a second connection electrode on the second insulating layer and electrically connected to at least a portion of the plurality of first connection electrodes through the second contact hole; and
a third insulating layer configured to cover the second connection electrode and on the second insulating layer.

14. The display panel of claim 13, wherein the second connection electrode comprises a third conductive layer comprising aluminum and a fourth conductive layer on the third conductive layer and comprising aluminum,
wherein the third insulating layer comprises:
a third sub insulating layer configured to cover at least a portion of a side surface of the third conductive layer and comprising a first inorganic material comprising silicon and a first organic material; and
a fourth sub insulating layer on the third sub-insulating layer configured to cover the fourth conductive layer and comprising a second organic material different from the first organic material.

15. The display panel of claim 13, wherein the second contact hole is defined in the second sub-insulating layer.

16. A display panel comprising:
a circuit layer; and
a light emitting element on the circuit layer,
wherein the circuit layer comprises:
a semiconductor pattern;
a first insulating layer comprising a first contact hole configured to expose a portion of the semiconductor pattern;
a plurality of first connection electrodes on the first insulating layer and electrically connected to the semiconductor pattern through the first contact hole; and
a second insulating layer configured to cover the plurality of first connection electrodes and on the first insulating layer,
wherein each of the plurality of first connection electrodes comprises:
a first conductive layer comprising aluminum; and
a second conductive layer on the first conductive layer and comprising aluminum,
wherein the second insulating layer comprises:
a first sub-insulating layer between a pair of adjacent first conductive layers; and
a second sub-insulating layer on the first sub-insulating layer, and
wherein at least a portion of a bottom surface of the second conductive layer is on the first sub-insulating layer.

17. A method comprising:
providing a semiconductor pattern and a first insulating layer on the semiconductor pattern; and
forming a plurality of first connection electrodes on the first insulating layer and electrically connected to the semiconductor pattern; and
forming a second insulating layer that covers the plurality of first connection electrodes,
wherein the forming of the plurality of first connection electrodes and the forming of the second insulating layer comprises:
forming a plurality of first conductive layers comprising aluminum on the first insulating layer;
providing a filling material between the plurality of first conductive layers to form a first sub-insulating layer that covers at least a portion of a side surface of each of the first conductive layers;
forming a plurality of second conductive layers comprising aluminum on the plurality of first conductive layers; and
forming a second sub-insulating layer that covers the plurality of second conductive layers,
wherein the filling material comprises a first inorganic material comprising silicon and a first organic material, and
wherein the method is a method for manufacturing a display panel.

18. The method of claim 17, wherein the forming of the first sub-insulating layer further comprises ashing a top surface of each of the first conductive layers after the providing of the filling material between the plurality of first conductive layers.

19. The method of claim 17, wherein a top surface of the first sub-insulating layer is below a top surface of each of the plurality of first conductive layers.

20. The method of claim 17, wherein the forming of the plurality of first conductive layers comprises:
forming a preliminary first layer comprising titanium on the first insulating layer;
forming a preliminary second layer comprising aluminum on the preliminary first layer; and
patterning the preliminary first layer and the preliminary second layer,
wherein the forming of the plurality of second conductive layers comprises:
forming a preliminary third layer comprising aluminum on the plurality of first conductive layers;
forming a preliminary fourth layer comprising titanium on the preliminary third layer; and
patterning the preliminary third layer and the preliminary fourth layer.

21. An electronic device comprising:
a display device comprising a display panel,
the display panel comprising:
a circuit layer; and
a light emitting element on the circuit layer,
wherein the circuit layer comprises:
a semiconductor pattern;
a first insulating layer comprising a first contact hole configured to expose a portion of the semiconductor pattern;
a plurality of first connection electrodes on the first insulating layer and electrically connected to the semiconductor pattern through the first contact hole; and
a second insulating layer configured to cover the plurality of first connection electrodes and on the first insulating layer,
wherein each of the plurality of first connection electrodes comprises:
a first conductive layer comprising aluminum; and
a second conductive layer on the first conductive layer and comprising aluminum,
wherein the second insulating layer comprises:
a first sub-insulating layer between a pair of adjacent first conductive layers; and
a second sub-insulating layer on the first sub-insulating layer configured to cover the second conductive layer, and
wherein the first sub-insulating layer comprises:
a first inorganic material comprising silicon; and
a first organic material.

22. The electronic device according to claim 21, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IOT) device, a smartwatch, a watch phone, or a head-mounted display (HMD).
